(19) United States
(12) Patent Application Publication
(10) Pub. No.: US 2026/0141146 A1
(43) Pub. Date: May 21, 2026

(54) OPTIMIZATION OF DESIGN LAYOUT DECOMPOSITION USING MACHINE-TRAINED NETWORK

(71) Applicant: D2S, Inc., San Jose, CA (US)

(72) Inventors: Donald Oriordan, Sunnyvale, CA (US); Akira Fujimura, Saratoga, CA (US)

(21) Appl. No.: 19/094,700

(22) Filed: Mar. 28, 2025

Related U.S. Application Data
(60) Provisional application No. 63/721,388, filed on Nov. 15, 2024.
(60) Provisional application No. 63/751,804, filed on Jan. 30, 2025.

(51) Int. Cl. G06F 30/3308; G06F 30/27

(52) U.S. Cl. CPC G06F 30/3308; G06F 30/27

(57) ABSTRACT

Some embodiments provide a method for decomposing a layout for a layer of an integrated circuit (IC) into two or more pattern layouts. The method receives a first decomposition of the layout of the IC layer. The first decomposition decomposes the layout into a first set of two or more pattern layouts. The method provides the first set of pattern layouts to a set of one or more machine-trained networks (MTNs) to identify a set of violations in the first set of pattern layouts. The set of violations is identified based on predicted manufactured shapes that are expected to be produced on the IC layer when the first set of pattern layouts is used to manufacture the IC. Based on the set of violations, the method decomposes the layout into a second decomposition, having a second set of pattern layouts, to use to manufacture the IC.

### BACKGROUND

In electronic design automation (EDA), design layouts for IC layers are often decomposed into multiple separate layouts (referred to as “colors”) such that multiple masks are fabricated for each layer (i.e., one mask per color). This is due to the inability to create masks to print design layout features (e.g., wires) that are too close to each other. However, in general the number of masks should be kept as small as possible due to the high cost of producing each mask.

The task of decomposing such a layout is typically modeled as a graph coloring problem, with the condition that any features within a threshold distance of each other must be assigned to separate colors. Graph coloring is known as a nondeterministic polynomial time (NP) hard problem, such that it is difficult or impractical to get a fully optimized solution for larger sizes (i.e., a typical IC layer). As such, the objective traditionally is to minimize the number of “conflicts” (features assigned to the same color that are within the threshold distance of each other) and “stitches” (features split into two or more conceptual features and assigned to different colors). Both conflicts and stitches can create errors in the eventually fabricated IC layer.

Various techniques have been proposed that use linear programming algorithms or semidefinite programming to ‘search’ the coloring space to find a good solution. Because this is an NP-hard problem, many coloring tools produce coloring solutions with some remaining conflicts and/or stitches. The goal of most such tools is to minimize the number of conflicts and stitches. With a resulting color-assigned solution containing some minimum number of conflicts/stitches, the circuit layout engineer is then tasked with modifying the layout to remove the remaining conflicts/stitches. This usually results in an (undesirable) increase in circuit area and engineering resources, possibly a negative impact to parasitics, delay to market, etc.

One significant problem with these approaches is that all conflicts are considered equal. That is, conflicts are measured solely based on a threshold distance-two features assigned to the same color are either outside of this threshold distance (and there is no conflict) or within the threshold distance (in which case a conflict exists). By requiring all features assigned to a color to be separated by a fixed distance, the optimization algorithms are often overly constrained, which negatively affects the quality of the results and/or the time to arrive at a solution.

If the threshold distance is set at a more aggressive (smaller) number, then a conflict/stitch minimized solution will be easier to find, but the manufacturing will be likely susceptible to “hotspots” (manufacturability problems). Certain patterns may be encountered in the design which, while their measured distances fall outside the threshold distance and are not considered a conflict, actually still do result in printability issues during manufacturing. This is because approaches based upon a single minimum-coloring-distance number cannot take all cases into account.

Furthermore, for designs with omni-directional features (e.g., wiring features that can run in any direction, rather than Manhattan-routed designs), the standard conflict definition makes even less sense. The features often diverge from each other rather than running parallel to each other, so using a single distance number to determine the existence of a conflict is less informative. Curvilinear designs exacerbate this problem even further, and even computing the distance between curvilinear features takes longer than for Manhattan features due to the large number of edges involved in the curvilinear polygon representation.

Another feature of traditional decomposition has been to attempt to balance the color masks such that each mask is assigned an approximately equal number of features, in an attempt to reduce printing features in isolation as masks with a small number of features are known to not print well. Such a global color balancing scheme may help a bit and local (i.e. location-based) balancing schemes may help a bit further, but neither scheme necessarily improves manufacturability. As such, layout decomposition techniques that improve the printability of the masks and/or enable faster convergence to coloring solutions are needed.

### BRIEF SUMMARY

Some embodiments provide a layout decomposition tool that accounts for context when decomposing a layout (for, e.g., a layer of an integrated circuit) into multiple separate layouts (also referred to as pattern layouts) for which to generate separate mask layouts for producing masks. Rather than identifying conflicts in color assignment based on a strict distance threshold, some embodiments identify violations in a context-dependent manner. More specifically, some embodiments simulate the manufactured shapes for the layer based on a particular decomposition and then identify violations in this simulated layer.

To simulate the manufactured shapes, some embodiments provide each of the multiple pattern layouts (after decomposition) to a machine-trained network (MTN) or other deep learning model. Such an MTN (e.g., a convolutional neural network) receives as input a layout having a set of design layout shapes (e.g., representing interconnect wires, vias, etc.) and outputs a representation of the IC layer actually manufactured based on that design (i.e., after accounting for mask layout generation and actually manufacturing the layer using a mask produced based on the mask layout).

To identify violations in the simulated layer, some embodiments combine the separate representations (i.e., the representations generated for each of the separate pattern layouts) into one as-manufactured representation and provide this to a second MTN (or other type of deep learning model). This second MTN outputs areas of violation based on various rules (e.g., predicted manufactured shapes that are too close together, certain types of angles or curves in the shapes, etc.).

Rather than looking at the assignment of features in the layout to generate a list of conflicts, some embodiments use the violations based on the predicted manufactured layer to compute a fitness score for the decomposition. This fitness score may be computed based on the number of identified violations and/or the size (i.e., area) of these violations. For instance, some embodiments compute the score as a weighted sum of the number of violations and the total area of the violations (with a larger score indicating a worse decomposition).

As such, the identification of violations is context-based in some embodiments. More specifically, the same set of shapes arranged in the same manner may result in a violation in one context when assigned to the same pattern layout but not in another context. That is, a first set of shapes assigned to one of the pattern layouts may be identified as a violation while a second set of shapes in the same relative arrangement as the first set of shapes does not result in a violation when assigned to one of the pattern layouts (either the same pattern layout as or a different pattern layout than the first set of shapes). The context that determines whether such a set of shapes results in a violation or not, in some embodiments, is the surrounding shapes in each region of the design layout. Based on the other surrounding shapes, generating a correct mask design for the first set of shapes may be more difficult than generating a correct mask design (or not possible) for the second set of shapes (e.g., due to interference from the mask shapes needed to correctly print the shapes nearby to the first set of shapes).

To optimize the decomposition, some embodiments perform an iterative process that uses the fitness score to improve the decomposition. At each iteration, one or more decompositions of the layout for the IC layer are identified. The predicted manufactured shapes for each decomposition are generated (e.g., using an MTN), and the decomposition is scored based on these predicted manufactured shapes. Based on these scores and/or the specific identified violations, one or more new decompositions are generated for the next iteration.

In some embodiments, the layout decomposition tool generates the new decompositions using a linear programming algorithm (e.g., integer linear programming), semidefinite programming, or other heuristics. In some such embodiments, one decomposition is generated at each iteration. The predicted manufactured shapes for that decomposition are simulated, and the decomposition is scored (e.g., using the fitness score described above). This fitness score based on the simulated manufactured shapes is then used to inform the next decomposition. Some embodiments determine whether the last decomposition improved or worsened the fitness score. In addition, the locations of the violations may be used to determine which areas need changes to the color assignments for the design layout features.

Furthermore, because the fitness score is a continuous function (unlike a simple counting of the number of conflicts, the area component of the fitness score is continuous), some embodiments use a gradient descent optimization method. In some such embodiments, the layout decomposition tool computes the gradient of the fitness score and uses gradient descent to modify the decomposition.

Other embodiments use algorithms that generate numerous different decompositions of the layout at each iteration. For a given iteration, the layout decomposition tool simulates the manufactured shapes for all of the different decompositions and computes fitness scores for each decomposition (e.g., using the techniques described above). The layout decomposition tool then identifies the subset of these decompositions with the best scores (e.g., the top 20%) and uses these to generate the next iteration of decompositions. Each decomposition in a new iteration may be generated by combining multiple different decompositions from the top-scoring subset (using a “genetic’ algorithm) or by randomly modifying individual decompositions from the top-scoring subset (using an “evolutionary” algorithm). For instance, in the latter case, if one thousand new decompositions are generated each iteration, then the best two hundred decompositions in one iteration can be used to each generate five new decompositions for the next iteration (by applying five different sets of random color assignment changes to each of the top-scoring decompositions).

When computing the fitness score for a decomposition, some embodiments additionally factor in other (e.g., neighboring) layers of the IC design. Thus, for instance, the fitness score for a particular metal (wiring) layer might factor in the relation of the metal layer to the neighboring z-axis connection (e.g., via and/or contact) layers and/or the metal layers above or below that layer. Specifically, some embodiments factor in the overlap of components of the current layer (i.e., the layer being evaluated) with components in the neighboring layers, such as wire ends overlapping with vias (a common type of overlap).

Some embodiments use the simulated manufactured shapes for a decomposition and compare these with predicted manufactured shapes for the neighboring layers to determine how well the shapes align. For instance, some embodiments compute the area of overlap for each line end that is supposed to overlap with a via and assign a score to the pair of overlapping shapes based on this area (e.g., with larger areas of overlap scoring better). These scores are then factored into the overall fitness score (applying weighting factors to each individual overlap score and/or to the overall overlap score vs. the single-layer violation score). Different embodiments will optimize the decomposition of a single layer while holding the neighboring layers static or optimize the decompositions of multiple layers simultaneously.

As noted above, some embodiments use one or more MTNs to evaluate each decomposition. The shape prediction MTN (that receives a layout as input and outputs the predicted manufactured shapes for that layout) may be trained based on (i) actual manufactured IC layers and/or (ii) layer simulations generated in another manner. For instance, when performing mask design, some embodiments use processes such as inverse lithography technology (ILT) that simulate lithographic processes used to manufacture IC layers based on a given mask design. Thus, to generate training data for an MTN that predicts manufactured shapes for a design layout, some embodiments use ILT to design a mask for the layout and simulate the IC layer that would be manufactured based on that mask. Using ILT software is a much slower process than running an MTN at inference, and thus a decomposition optimization process that relies on simulation of the predicted shapes is much faster when using an MTN (or another trained deep learning model) than if ILT had to be run for each layout of every decomposition being evaluated (running a separate iterative optimization process inside of an iterative optimization process would be prohibitively slow).

The violation identification MTN of some embodiments (that receives a predicted manufactured layer as input and outputs violation areas) may be trained based on, e.g., design rule check data. To train such a network, some embodiments use simulated manufactured layers as inputs with corresponding identified rule violations as outputs. These rule violations can be determined based on, e.g., geometric, equation-based, or circle-tracing methods.

In the above description, the actual generation of a decomposition is performed using various methods such as assignment of nodes in a graph to different colors (i.e., different separate layouts). Some embodiments instead use an MTN to perform the decomposition. In this case, the MTN receives a layout for a layer (or a portion of such a layer) and outputs assignment of the features of that layout to multiple colors. The training data for such an MTN may be the design layouts described above (as inputs) and the optimized coloring assignments generated using the above process in some embodiments.

In some embodiments, the layout decomposition tool divides the layout into tiles and uses each tile as a separate input into the decomposition MTN (e.g., the same instance of the MTN or multiple separate instances). For each tile, the MTN performs a separate assignment of the design layout features within the tile, which are then stitched together for the layout as a whole. In some such embodiments, this allows the parallelization of the assignments, as multiple MTN instances can assign features for multiple tiles in parallel.

Other embodiments also include halo regions around each tile so that the input area for one tile overlaps with multiple other tiles. In this case, the MTN assigns the features located in the halo areas (i.e., that are part of other tiles) as either preferences or strict assignments that are accounted for when the MTN assigns the features in those tiles. In some such embodiments, the decomposition process involves first using the MTN to assign the features of a center tile (e.g., the most central tile in the design layout or a randomly selected interior tile). Next, the MTN is used to assign one of the neighboring tiles, but with a subset of its features (i.e., the features at least partially within the halo region) pre-assigned. The features within the first ring of (8) tiles around the first tile are each assigned by separately providing the tiles with a subset of their features pre-assigned to the MTN, and then the process moves to the next ring of tiles. This process is performed, radiating outwards, until all of the features in the design layout are assigned. By using the halo regions of each tile to pre-assign features the next tile, this process ensures consistency throughout the decomposition.

After performing decomposition using the MTN, some embodiments then use verification techniques (e.g., the verification techniques described above that use a shape prediction MTN and/or a violation detection MTN). Ideally, the decomposition MTN (or multiple MTN instances in the case of tiling) will have optimally assigned the features of the design layout such that the fitness score for the decomposition is below a threshold. However, if the decomposition should be performed again, some embodiments use the decomposition MTN again. To ensure that the MTN (typically a deterministic algorithm) does not output the same decomposition (i.e., the same coloring assignments for the design layout features), some embodiments modify the input. For a single MTN instance that takes as input the entire design layout, some embodiments pre-assign several features differently than in the previous decomposition. For the tiling process, some embodiments select a different starting tile for feature assignment.

Using a tiling process for the MTN inputs provides benefits both during inference (the decomposition process) as well as for training the MTN. At inference, the smaller input bounds the size of the network and thus the time required for each tile to have its features assigned. For training, the tiling process simplifies training (i.e., the size of the network need not be as large because the size of the input images is smaller) and enables the creation of many more training inputs. For instance, rather than an optimized decomposition resulting in only a single training input, one optimized decomposition for a design layout can be used to generate many training inputs.

The preceding Summary is intended to serve as a brief introduction to some embodiments of the invention. It is not meant to be an introduction or overview of all inventive subject matter disclosed in this document. The Detailed Description that follows and the Drawings that are referred to in the Detailed Description will further describe the embodiments described in the Summary as well as other embodiments. Accordingly, to understand all the embodiments described by this document, a full review of the Summary, Detailed Description, the Drawings and the Claims is needed. Moreover, the claimed subject matters are not to be limited by the illustrative details in the Summary, Detailed Description, and Drawings.

### BRIEF DESCRIPTION OF THE DRAWINGS

The novel features of the invention are set forth in the appended claims. However, for purposes of explanation, several embodiments of the invention are set forth in the following figures.

FIG. 1 conceptually illustrates different types of feature shapes that are described in this application.

FIG. 2 conceptually illustrates a process of some embodiments for optimizing a layout decomposition.

FIG. 3 conceptually illustrates the assignment of a set of eight features of a design layout portion to two different layouts of a decomposition.

FIG. 4 conceptually illustrates the assignment of the same eight features of the design layout portion in FIG. 3 to a different pair of layouts of a different decomposition.

FIG. 5 conceptually illustrates the assignment of the eight features of the design layout in FIG. 3 to three layouts of a decomposition.

FIG. 6 conceptually illustrates that different decompositions will result in different representations of predicted manufactured layers.

FIG. 7 conceptually illustrates an example input and output of a violation detection MTN of some embodiments.

FIG. 8 conceptually illustrates an overlay of the MTN output on top of the predicted manufactured layer from FIG. 7.

FIG. 9 conceptually illustrates an example of the same pair of shapes arranged in the same manner resulting in a violation in a first context while not resulting in a violation in a second context, based on the surrounding shapes.

FIG. 10 illustrates an example of a curved edge of an interconnect segment that is converted into a raster tone map through rasterization.

FIG. 11 conceptually illustrates a process of some embodiments for optimizing a design layout decomposition using an iterative process that generates numerous different decompositions each iteration.

FIG. 12 conceptually illustrates the generation of ten different decompositions of a design layout and the resulting ten different predicted manufactured layers.

FIG. 13 conceptually illustrates the generation of fitness scores for each of the predicted layers of FIG. 12.

FIG. 14 conceptually illustrates a generation of ten new decompositions based on the best scoring decompositions of FIG. 12.

FIG. 15 conceptually illustrates a process of some embodiments for computing a fitness score for a decomposition of a design layout for a first layer using both manufacturability violations for the first layer as well as the interaction of the first layer with at least one additional layer.

FIG. 16 conceptually illustrates an example of a decomposition for a portion of a first layer with overlaps between the features of the first layer and features of other layers.

FIG. 17 conceptually illustrates an example of the overlap resiliency for two different overlaps between predicted manufactured shapes.

FIG. 18 conceptually illustrates a process of some embodiments for creating training data and using this training data to train a shape prediction MTN.

FIG. 19 conceptually illustrates a process of some embodiments for creating training data and using this training data to train a violation identification MTN.

FIG. 20 conceptually illustrates an overall process for decomposing a layout and designing a set of masks for the layout using a set of MTNs.

FIG. 21 conceptually illustrates a process of some embodiments for using an MTN to decompose a layout that is divided into tiles.

FIG. 22 conceptually illustrates the tiling of a design layout.

FIG. 23 conceptually illustrates a design layout region divided into a set of twenty-five tiles.

FIGS. 24 and 25 conceptually illustrate alternative patterns for parallelization of the decomposition of a layout divided into tiles.

FIG. 26 conceptually illustrates a process of some embodiments for creating training data and using this training data to train a decomposition MTN.

FIG. 27 conceptually illustrates a process of some embodiments for designing and manufacturing an IC.

FIG. 28 conceptually illustrates a computer system with which some embodiments of the invention are implemented.

### DETAILED DESCRIPTION

In the following detailed description of the invention, numerous details, examples, and embodiments of the invention are set forth and described. However, it will be clear and apparent to one skilled in the art that the invention is not limited to the embodiments set forth and that the invention may be practiced without some of the specific details and examples discussed.

Some embodiments provide a layout decomposition tool that accounts for context when decomposing a design layout (for, e.g., a layer of an integrated circuit) into multiple separate layouts for which to generate separate mask layouts for producing masks. Rather than identifying conflicts in color assignment based on a strict distance threshold, some embodiments identify violations in a context-dependent manner. More specifically, some embodiments simulate the manufactured shapes for the layer based on a particular decomposition and then identify violations in this simulated layer.

To simulate the manufactured shapes, some embodiments provide each of the multiple separate layouts (after decomposition) to a machine-trained network (MTN) or other deep learning model. Such an MTN (e.g., a convolutional neural network) receives as input a layout having a set of design layout shapes (e.g., representing interconnect wires, vias, etc.) and outputs a representation of the IC layer actually manufactured based on that design (i.e., after accounting for mask layout generation and actually manufacturing the layer using a mask produced based on the mask layout).

To identify violations in the simulated layer, some embodiments combine the separate representations (i.e., the representations generated for each of the separate layouts) into one as-manufactured representation and provide this to a second MTN (or other type of deep learning model). This second MTN outputs areas of violation based on various rules (e.g., predicted manufactured shapes that are too close together, certain types of angles or curves in the shapes, etc.).

Rather than looking at the assignment of features in the layout to generate a list of conflicts, some embodiments use the violations based on the predicted manufactured layer to compute a fitness score for the decomposition. This fitness score may be computed based on the number of identified violations and/or the size (i.e., area) of these violations. For instance, some embodiments compute the score as a weighted sum of the number of violations and the total area of the violations (with a larger score indicating a worse decomposition).

Prior to describing the decomposition process in more detail, certain aspects of IC design and manufacturing will be described. An IC includes a set of several layers, typically manufactured on a substrate. These layers typically include the substrate layer itself (the base semiconductor layer of the IC), one or more device layers (in which transistors are located), one or more metal layers (also referred to as interconnect layers or wiring layers, which are layers through which metal interconnects traverse in a plane), and one or more intervening layers. The intervening, or dielectric layers, are spaced between the device and metal layers, and allow for z-axis connections (taking, e.g., the plane of the metal layers as being parallel to the x-y plane). These intervening layers include via layers between pairs of metal layers and contact layers between device layers and metal layers, with vias and contacts being two examples of z-axis connections that traverse between at least two layers of the IC.

The design of these layers is in some embodiments defined by a design layout for the IC. In some embodiments, a design layout includes a layout for each layer (e.g., each device layer, each wiring layer, and/or each via layer). For a given layer, the design layout defines the shapes of the components (e.g., the interconnect wiring segments, the vias, etc.) that are defined on that layer.

To manufacture the layers and their components based on the design layout, one or more photomasks (referred to herein as “masks”) are created and used. A mask is an opaque plate with transparent areas that let in light through a defined pattern. The transparent areas of a mask are determined by a corresponding mask layout. In some embodiments, a mask layout has an overall mask image for each device or wiring layer. The overall mask image for each layer can be decomposed into one or more individual mask images, for instance through the use of a coloring technique that assigns one of several different colors to each shape in the overall mask image in order to assign the shape to the individual mask image of that color. Each mask image of each layer can be used to produce a mask that can then be used to fabricate the components of that layer.

That is, just as a design layout includes multiple design layers that correspond to eventually fabricated IC layers (also referred to herein as wafers), a mask layout includes multiple mask layers that correspond to eventually fabricated masks (which are themselves used to fabricate the IC layers). In some embodiments, each layer of a design layout corresponds to a layer of the mask layout, which can include one or more mask images. As noted above, in many cases it is not possible to accurately fabricate an IC layer using only a single mask for a layer, and thus a multi-patterning (layout decomposition) tool is employed to divide the design layout for a layer into multiple layouts. Separate masks are then designed and produced for each of these multiple layouts.

Mask images define the mask layout in the geometric domain, and show the pattern of the transparent areas, including primary transparent areas that will fabricate components of the design and secondary transparent areas (e.g., SRAFs) that will aid in the fabrication of the components of the design (i.e., by letting more light shine through the mask). In some embodiments, the mask images are rasterized into mask pixel images, which define the mask layout in the pixel domain. It should be noted that, due to the nature of the mask-making process, the mask shapes (1) do not necessarily correspond 1:1 to the fabricated IC components (i.e., to the design layout shapes) and (2) cannot always be easily correlated to individual IC components (i.e., to design layout shapes) by human observation.

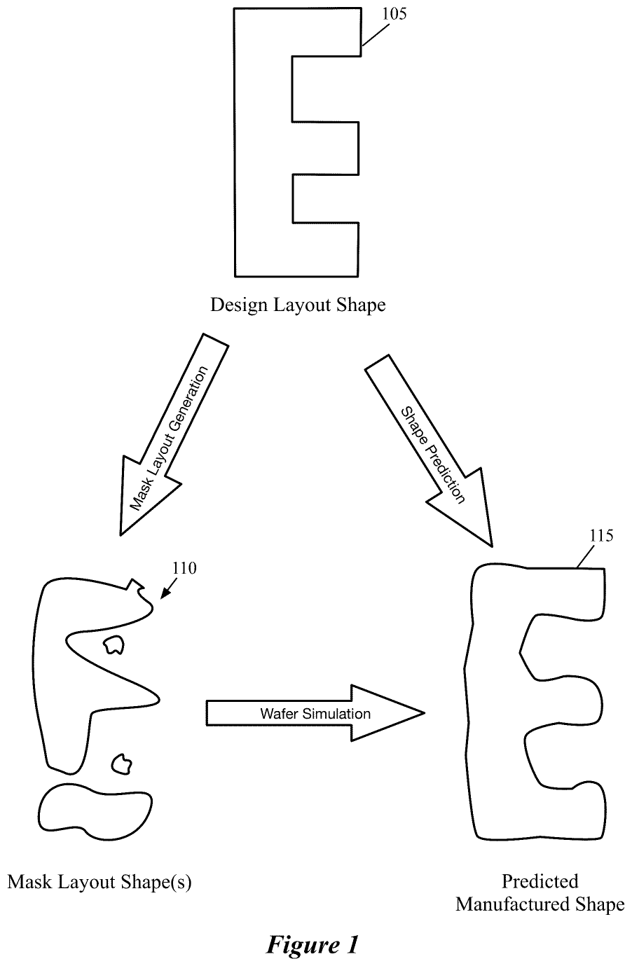

FIG. 1 conceptually illustrates different types of feature shapes that are described in this application. These different types of shapes include design layout shapes 105, mask layout shapes 110, and predicted manufactured shapes 115. The design layout shapes 105 are shapes that are part of the actual design layout (e.g., the design layout output by the physical design process). In many cases, these shapes are rectilinear shapes (i.e., with straight lines, in some such cases only including straight lines at certain angles relative to each other). In other examples, the design layout shapes 105 may have curvilinear features (i.e., at least some of the contours of the shapes may be curved).

Mask layout shapes 110 are generated by a mask production process from the design layout shape (or from a target wafer image shape that can be generated from the design layout shapes). In many cases, the mask layout shapes 110 used for manufacturing a particular design layout shape 105 do not closely resemble that design layout shape 105 or only partly resemble the design layout shape 105. In addition, as shown in this case, sometimes multiple separate shapes are used to fabricate a single IC component corresponding to a single design layout shape 305. Rather than being smooth-edged shapes, in certain cases various small features (e.g., serifs) may be added to the mask layout shapes 110 to better fabricate the IC components. In some cases, very small shapes referred to as sub-resolution assist features (SRAFs) may be included in the mask layout. In addition, due to the nature of IC fabrication and the very small distances involved, mask layout shapes 110 that primarily are designed for the fabrication of one IC component can have an effect on the shape of other nearby IC components.

During mask design, the mask layout shapes 110 are often iteratively modified in order to determine the shapes that will best result in manufactured components matching the design layout shapes 105 (or target wafer image shapes that may be generated by applying various corner-rounding algorithms to the design layout shapes 105). Part of this mask optimization process includes wafer simulation, in which various techniques are used to generate predicted manufactured shapes 115 (also referred to as simulated manufactured shapes or simulated wafer shapes) based on the current mask layout shapes. This wafer simulation process may use lithographic simulation in some embodiments, which simulates the various lithographic operations used to fabricate an IC layer using a mask (e.g., optical exposure, photoresist development, and etching). Other embodiments use MTNs (e.g., neural networks) to generate the simulated wafer shapes 115 from a mask layout. As described further herein, some embodiments also generate predicted manufactured shapes 115 directly from the design layout shapes 105 using MTNs (e.g., neural networks) or other deep learning models (e.g., by training these models using the results of mask design and wafer simulation to then avoid the lengthy mask design process when evaluating layout decomposition).

The masks generated through mask design and optimization are used to fabricate an IC layer (e.g., a metal layer, a via layer, a contact layer, etc.). In some embodiments, a design layout for an IC layer is decomposed into two or more separate layouts (“colors”), with separate masks designed for each color. The IC layer is then fabricated using this mask or set of two or more masks (if layout decomposition is performed).

A substrate is a type of base board used to package a bare IC chip. A wafer is an example of a substrate, and is a thin slice of semiconductor (e.g., silicon) material used for the fabrication of ICs. Light is shone through a mask (i.e., through the mask's transparent areas) onto a wafer to fabricate a layer of an IC on the wafer. In some embodiments, light is shone through multiple masks, one at a time, to fabricate a layer of an IC. This process involves the application of photoresist to the substrate, such that after the light is shone through the mask or masks for a layer, areas that received the light have different chemical properties than those that did not receive light.

Vias are small holes through one or more via layers (i.e., through inter-layer dielectric material) to intersect with conductors on each of the adjacent metal layers (e.g., directly with the interconnect segments, or with via pads that connect to the interconnect segments). Vias are examples of z-axis components, specifically z-axis connections that traverse between at least two layers. Other examples of z-axis components are contacts that form z-axis connections between interconnect wiring segments in a metal layer and a device layer of an IC as well as z-axis capacitors, in which metal components in two layers do not physically connect but instead form a capacitor.

In some embodiments, via holes are plated with metal (e.g., copper) to form an electrical connection through the insulating (dielectric) layers. Contact layers are similar to via layers but connect metal (wiring/interconnect) layers to device layers rather than metal layers to other metal layers. That is, vias refer to z-axis components that connect interconnect lines (e.g., lines representing wires) on different metal layers and higher layer interconnect lines to circuit elements, while contacts refer to z-axis components that connect parts of circuit elements on the IC substrate with one or more lower metal layers (e.g., metal layer 1) to form circuit elements (e.g., to form transistors). Because vias and contacts connect parts of multiple layers together, it is important for the metal layer components to properly cover the entirety of the vias and contacts (i.e., it is important to have proper overlap for certain z-axis components).

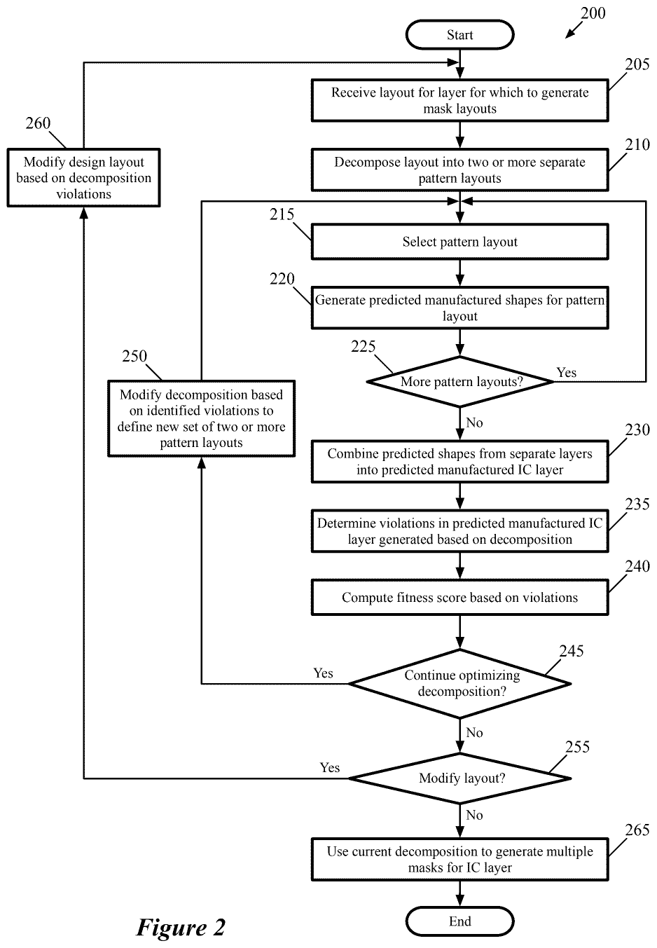

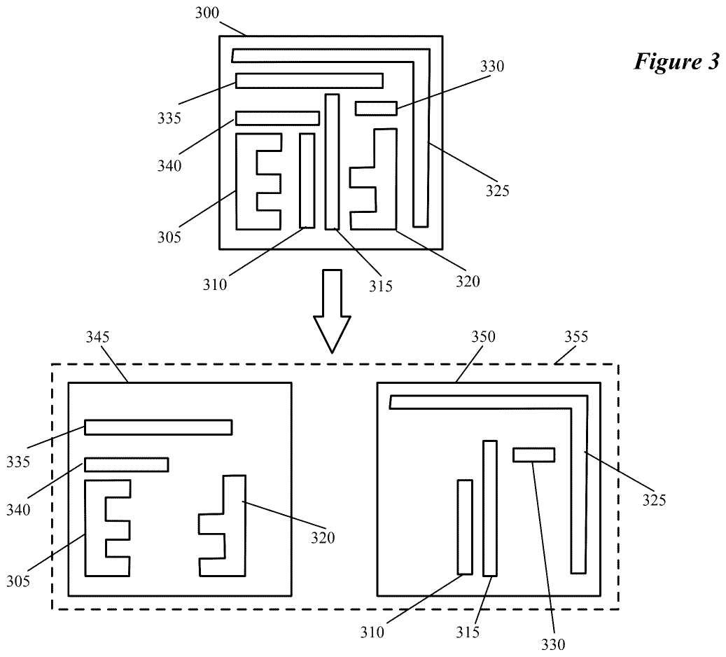

Having introduced the different types of feature shapes described herein as well as the mask and IC fabrication process, FIG. 2 conceptually illustrates a process 200 of some embodiments for optimizing a layout decomposition. The layout decomposition process 200 of some embodiments may be performed by a layout decomposition tool, which may be a part of a mask design tool (e.g., within a larger electronic design automation (EDA) process) or a separate tool that is used prior to mask design. The process 200 will be described in part by reference to FIGS. 3-9, which illustrate examples of various layout decompositions, manufactured shape simulation, and violation detection operations.

As shown, the process 200 receives (at 205) a layout for a layer (e.g., for a layer of an IC) for which to generate mask layouts. The layouts of some embodiments include numerous features, or shapes. These features represent layer components, such as interconnect (wiring) segments for a metal (wiring) layer, via holes for a via layer, etc. The layout may restrict features to specific angles or allow an omnidirectional set of features. Common layouts with the features restricted to certain angles include Manhattan layouts (i.e., with all of the features arranged either horizontally or vertically) or layouts allowing specific diagonal angles (e.g., features arranged horizontally, vertically, and at 45° angles). Other layouts include omnidirectional rectilinear layouts (i.e., layouts with entirely straight lines but at any angle) as well as curvilinear layouts (i.e., layouts in which some of the features may have curved edges). For ICs, the received layout (also referred to herein as a design layout) is typically the output of a physical design process that includes operations such as floorplanning, placement, routing, and compaction (and has often been verified by a layout verification tool). It should be understood that, while described herein as a design layout for an IC layer, the processes described herein generally take this layout as a given output of the physical design process rather than resulting in changes to the physical design layout (as would occur during the physical design process). However, in some embodiments, if a successful decomposition cannot be found, then a circuit designer may return to the physical design process and modify this design layout.

The process 200 then decomposes (at 210) the received layout into two or more separate layouts, also referred to herein as pattern layouts. Different embodiments may use different techniques for generating this initial decomposition. As described in more detail below, in some embodiments an MTN or other deep learning model generates decompositions. Other embodiments use graph-based techniques, in which each of the features is assigned as a node in a graph and two features that are within a threshold distance are connected as nodes. If no cycles of three or more nodes exist, then decomposition into two layouts is relatively simple. However, in a typical IC layer, many such cycles exist and identifying a solution with no conflicts is an NP-hard problem. As such, some embodiments perform an initial assignment either randomly or by stepping through the graph in order and assigning nodes to different colors in a next neighbor manner. In addition, while some embodiments always assign each feature to one of the pattern layouts, other embodiments allow for some of the features to be split between two different pattern layouts (i.e., assigning a first portion of a feature to one pattern layout and a second portion of that feature to a second pattern layout).

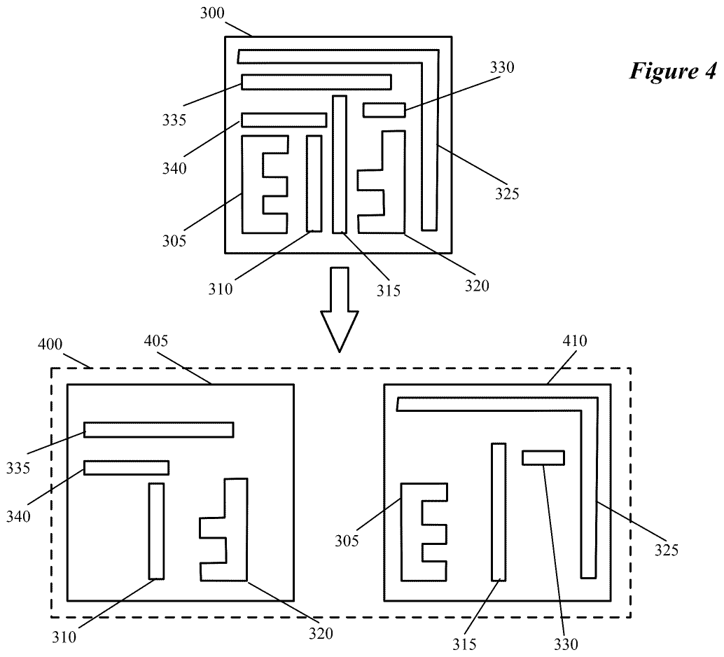

FIG. 3 conceptually illustrates the assignment of a set of eight features 305-340 of a design layout portion 300 to two different pattern layouts 345 and 350 (i.e., two different colors) of a decomposition 355. As shown, in this example, the features 305, 320, 335, and 340 are assigned to the first layout 345 while the features 310, 315, 325, and 330 are assigned to the second layout 350. FIG. 4 conceptually illustrates the assignment of the same eight features 305-340 of the design layout portion 300 to a different pair of pattern layouts 405 and 410 of a different decomposition 400. In this second example, the features 310, 320, 335, and 340 are assigned to the first layout 405 while the features 305, 315, 325, and 330 are assigned to the second layout 410.

It should be understood that this example is a simple example with only eight features and that typical design layouts may have many more features (e.g., thousands of different features) per layer such that decomposition is a more difficult task as the number of different decomposition options available for a single layer increases exponentially with the number of features to be assigned. While both of the examples in FIGS. 3 and 4 equally divide the features between two separate layouts (two color assignments), equal division is not typically a requirement (although benefits have been shown to avoiding extremely unequal assignment of features).

In addition, different embodiments use different numbers of pattern layouts in a decomposition. In many cases, three or four separate layouts (corresponding to separate masks) are needed to decompose a design layout with the features adequately separated. However, because each mask is individually expensive to fabricate, a smaller number of layouts is preferable whenever possible.

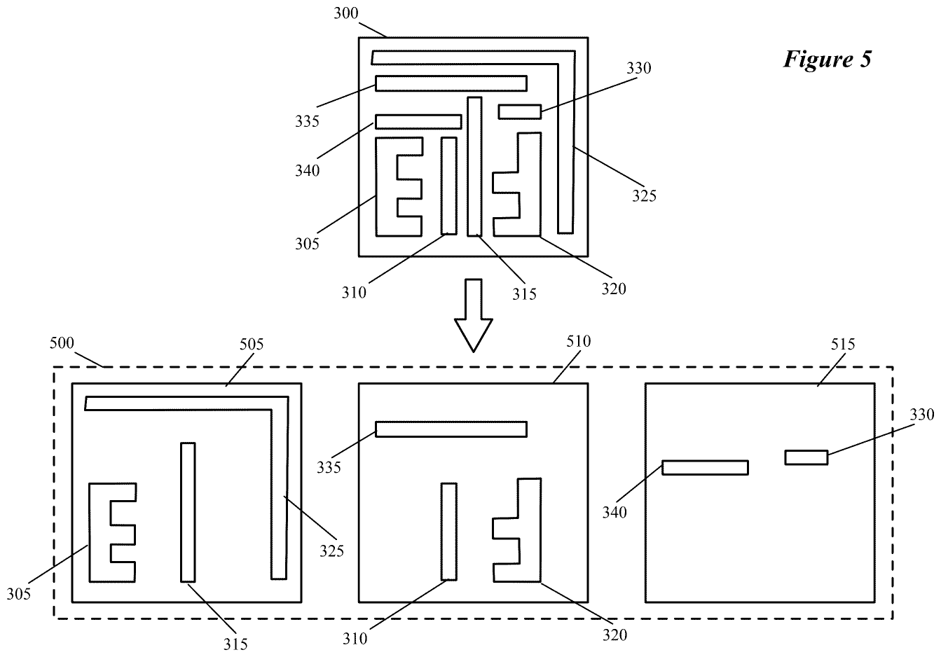

FIG. 5 conceptually illustrates the assignment of the eight features 305-340 of the design layout 300 to three pattern layouts 505-515 of a decomposition 500. In this example, the features 305, 315, and 325 are assigned to the first layout 505, the features 310, 320, and 335 are assigned to the second layout 510, and the features 330 and 340 are assigned to the third layout 515.

In some embodiments, the number of separate layouts used for a decomposition is a pre-specified parameter (e.g., by a circuit designer). Other embodiments attempt to minimize the number of layouts while also ensuring that the decomposition satisfies other requirements (e.g., optimizing a fitness score used to evaluate decompositions). Some such embodiments use the number of separate layouts as a factor in the fitness score (with fewer layouts resulting in a more optimized score). Other such embodiments initially attempt to identify a two-color decomposition that satisfies the other requirements, then move on to three-color decompositions if no such decomposition can be found after a given number of iterations, then move to four-color decompositions, etc.

Returning to FIG. 2, once the initial decomposition has been generated, the process 200 evaluates and scores that decomposition. As shown, the process 200 selects (at 215) one of the separate pattern layouts of the decomposition (i.e., one of the color assignments). It should be understood that the process 200 is a conceptual process and that the process does not evaluate each individual layout one after another in some embodiments. Rather, the layout decomposition tool, in some embodiments, performs operations in parallel for some or all of the separate pattern layouts.

The process 200 then generates (at 220) predicted manufactured shapes for the pattern layouts. These predicted manufactured shapes represent the shapes (e.g., wires, via holes, etc.) that will be manufactured for the current layer based on the use of a mask designed to manufacture that layout. In some embodiments, this shape prediction operation accounts for (i) mask design to design a mask for optimally fabricating the design layout, (ii) mask fabrication, and (iii) actual manufacturing of the layer using the fabricated mask.

To simulate the manufactured shapes, some embodiments provide the selected pattern layout to an MTN (e.g., a convolutional neural network) or other deep learning model. Such an MTN receives as input a layout having a set of design layout shapes (e.g., representing interconnect wires, vias, etc.) and outputs a representation of the IC layer actually manufactured based on that design (i.e., after accounting for mask layout generation and actually manufacturing the layer using a mask produced based on the mask layout). In general, these predicted manufactured layers (also referred to as simulated wafers or predicted wafers) will have curvilinear features replacing straight lines and right angles, as true right angles (at the microscopic level) are generally not actually manufacturable.

Using a deep learning model such as an MTN enables evaluation of decompositions based on actual results rather than simple heuristics such as threshold-based conflicts. Once such a model is trained, generating predicted manufactured shapes for a layout is a very quick process, especially compared to the alternatives of actually using a mask optimization and wafer simulation process (e.g., inverse lithography technology (ILT), which is often used for the actual process of mask design).

The process 200 determines (at 225) whether more of the separate pattern layouts remain. If additional such pattern layouts remain, the process 200 returns to 215 to select another one of the pattern layouts and generate the predicted manufactured shapes for that layout, until all of the patten layouts have been selected.

Once predicted manufactured shapes have been generated for all of the separate layouts pattern of the decomposition, the process 200 combines (at 230) the predicted shapes from these separate layers into a representation of the entire predicted manufactured IC layer. Other embodiments, it should be noted, do not combine the predicted shapes of the different pattern layouts and perform the subsequent evaluations of these predicted shapes separately for each of the coloring assignments. However, combining the predicted shapes enables (i) evaluation of all of the predicted manufactured shapes in one operation and (ii) evaluation of the interaction of all of the predicted manufactured shapes as they would interact on the IC layer.

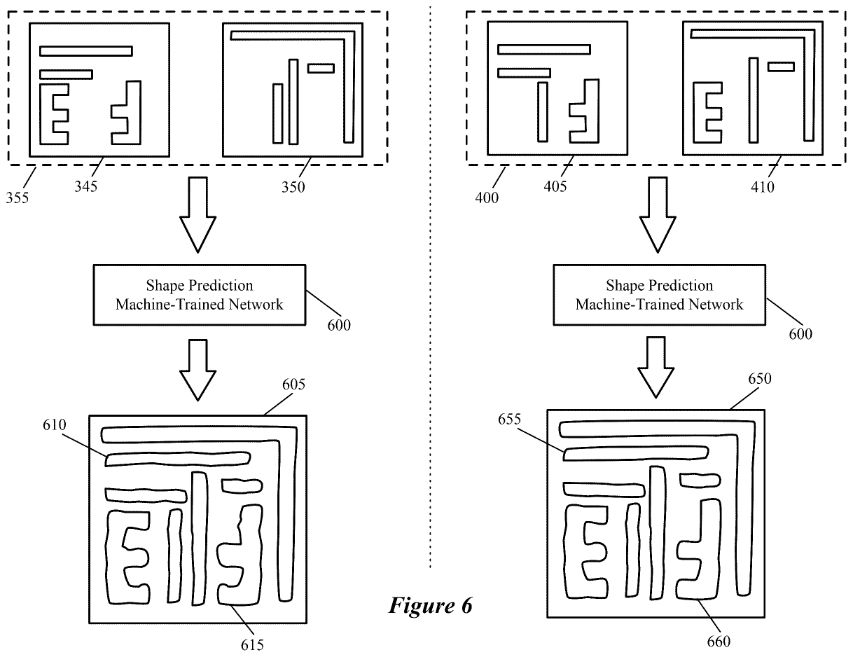

FIG. 6 conceptually illustrates that different decompositions will result in different representations of predicted manufactured layers (or portions of layers). Specifically, this figure illustrates that the layouts 345 and 350 of the decomposition 355 as well as the layouts 405 and 410 of the decomposition 400 (from FIGS. 3 and 4 respectively) are provided to a shape prediction MTN 600 of some embodiments and then combined into their respective predicted layers 605 and 650. That is, in some embodiments the first predicted layer 605 is a combination of two outputs of the network 600 based on layouts 345 and 350 as inputs while the second predicted layer 650 is a combination of another two outputs of the network 600 based on layouts 405 and 410 as inputs.

This MTN 600 is trained to receive a design layout or design layout portion and output the predicted shapes representing the eventually manufactured layer. As described further below, the network 600 is trained using actual manufactured IC layers (given a design layout) and/or simulations generated in another manner (e.g., using mask design optimization tools that simulate IC layer representations as part of the mask optimization). Based on this training data of design layout inputs and corresponding ground truth manufactured and/or simulated outputs, the MTN is trained to accurately output the manufactured shapes for a given design layout or layout region.

As shown in the figure, the two different decompositions 355 and 400 result in different predicted manufactured shapes. The general nature of the shapes is similar, as generally any decomposition of a validated design layout will result in the correct number of manufactured shapes in the correct arrangement, with the differences being small changes in the details of the manufactured shapes. Thus, for instance, the predicted shape 610 in the first predicted layer 605 is less straight than the corresponding predicted shape 655 in the second predicted layer 650, and the predicted shape 615 in the first predicted layer 605 has more deformities around its edges than the corresponding predicted shape 660 in the first predicted layer 650. These are only two examples of the numerous slight differences between the predicted manufactured layers 605 and 650, which may indicate (i) the manufacturability of the layer given the different decompositions and (ii) the performance of an IC manufactured using the decomposition.

After combining the predicted manufactured shapes from the multiple separate layouts into one predicted manufactured IC, the process 200 determines (at 235) violations in the predicted manufactured IC layer. Whereas existing coloring assessments simply look at threshold distances in the design layout itself, the process 200 determines violations based on various factors by assessing the actual manufacturability of the decomposition. As such, as described in more detail below, the identification of the violations is context-based.

In some embodiments, the types of violations identified can include shape width violations, shape proximity violations, and/or curvature violations, among other types. Shape width violations are identified when an as-manufactured shape (representing, e.g., an interconnect wire of the layer) is too narrow in a particular location. Shape proximity violations are identified when two shapes (e.g., two interconnect wires) would be manufactured too close to each other. Finally, curvature violations identify cases in which the curvature of the shape edge is too great in a particular direction (e.g., too concave and/or too convex) to be reliably manufacturable.

In some embodiments, the violations are identified by a second MTN or other deep learning model that receives as input a predicted manufactured layer (or portion of a layer) and outputs a set of violation areas for that predicted manufactured layer based on various rules (e.g., the shape width, shape proximity, and/or curvature rules mentioned above). Just as the shape prediction network can be trained by using design layouts as known inputs and the actual or simulated manufactured shapes for those design layouts as the corresponding known outputs, the violation identification MTN can be trained by using actual or simulated manufactured layers (or layer portions) as training inputs and the corresponding violation identifications as known outputs. These ground truth violation identifications, in some embodiments, are generated using other manufacturability rule checkers, in some embodiments. Some embodiments, rather than using an MTN to determine the violations, use a set of manufacturability rule checks that identify the violations algorithmically.

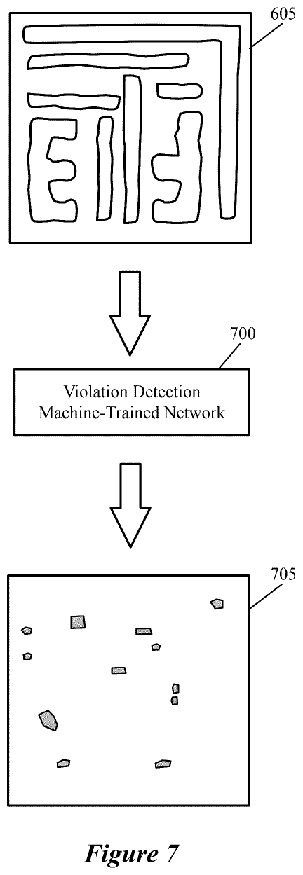

FIG. 7 conceptually illustrates an example input and output of a violation detection MTN 700 of some embodiments. As shown, the input to this network 700 is the predicted manufactured layer 605 (or layer portion) and the output 705 is a set of regions in which violations are detected. In this case, the network 700 identifies 12 different violations (shown as gray areas in the output 705). These violation polygons have different areas and may be identified as violations by the MTN 700 for various different reasons.

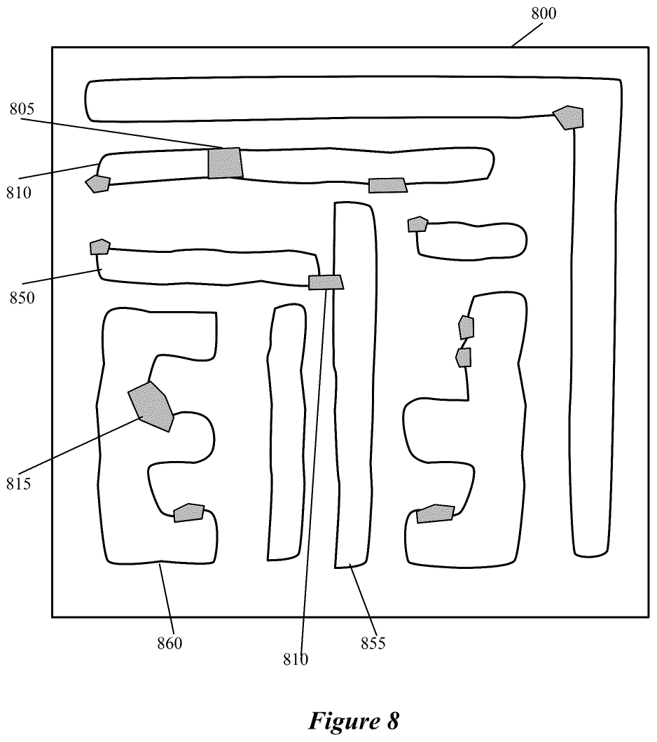

FIG. 8 conceptually illustrates an overlay 800 of the MTN output 705 on top of the predicted manufactured layer 605. This overlay 800 indicates where in the predicted manufactured layer the violations identified by the network 700 occur (and thus what type of violations were identified). For instance, the violation 805 is a shape width violation identified because a portion of the predicted shape 610 is too narrow in a particular location. The violation 810 is a shape proximity violation identified because the predicted shapes 850 and 855 are too close together, while the violation 815 is a curvature violation (as are many of the other identified violations) identified because a portion of the shape 860 curves too sharply. It should be noted that these types of violations are merely provided as examples, and many other types of violation may be identified in different embodiments.

Because the identification of violations is performed using the predicted manufactured shapes for a layer rather than direct measurement of distances in a design layout, the identification of violations is context-based in some embodiments. More specifically, the same set of shapes arranged in the same manner may result in a violation in one context when assigned to the same layout but not in another context.

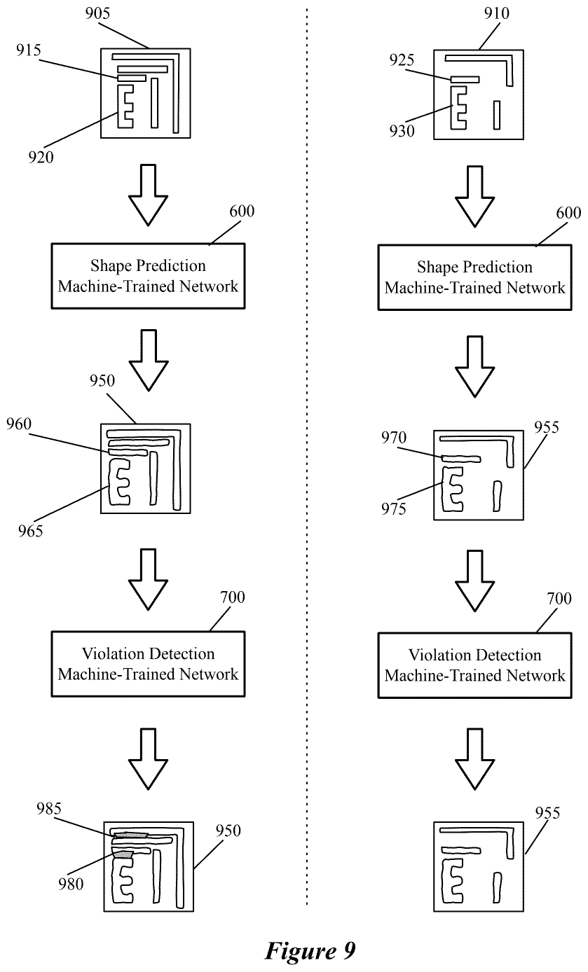

FIG. 9 conceptually illustrates an example of the same pair of shapes arranged in the same manner resulting in a violation in a first context while not resulting in a violation in a second context, based on the surrounding shapes. As shown, two layout portions 905 and 910 are provided to a shape prediction MTN 600) to generate respective predicted manufactured layer regions 950 and 955. These two layout portions 905 and 910 may represent two different regions of the same layout in one decomposition, regions of different layouts in the same decomposition, or the same layout region in two different decompositions of a layout. In the first two cases, it should be understood that the overall layouts of the decomposition are larger than the portions shown and that the portions 905 and 910 represent different regions of these larger layouts (i.e., either represent different regions of the same layout or non-overlapping regions of different separate layouts of the same decomposition). Some embodiments provide the one or more layout in its entirety to the MTN 600, rather than just the small layout portions 905 and 910.

The layout portion 905 includes two shapes 915 and 920 while the layout portion 910 includes two shapes 925 and 930 that have the same design layout shape and arrangement as the two shapes 915 and 920 in the first layout portion 905. In addition, each of the layout portions 905 and 910 include different other shapes in the neighborhood context of these pairs of shapes (the first layout portion 905 includes three other shapes while the second layout portion 910 includes two other shapes).

The shape prediction MTN 600, as noted, outputs the predicted manufactured layers that include the predicted manufactured layer regions 950 and 955. Despite the design layout shapes 915 and 920 having the same shape and relative arrangement as the design layout shapes 925 and 930, the predicted manufactured shapes 960 and 965 (corresponding to the design layout shapes 915 and 920) differ from the predicted manufactured shapes 970 and 975 (corresponding to the design layout shapes 925 and 930) in small but noticeable ways (e.g., the top section of the predicted manufactured shape 965 is slightly larger than the corresponding section of the predicted manufactured shape 975).

The predicted manufactured layer regions 950 and 955 are provided to a violation detection MTN 700 (e.g., as sections of either the same predicted manufactured layer or two different predicted manufactured layers resulting from two different decompositions). As described above, the violation detection MTN 700 outputs violation regions. In this case, the predicted manufactured layer region 950 includes two identified violations 980 and 985 while the predicted manufactured layer region 955 does not have any violations identified. The violation 980 is a shape proximity violation between the predicted manufactured shapes 960 and 965 (i.e., indicating that these shapes are too close), but no such violation is found between the shapes 970 and 975.

Thus, as shown in this figure, a set of design layout shapes assigned to one of the layouts (in this case shapes 915 and 920) may result in a violation while a second set of shapes (in this case shapes 925 and 930) in the same relative arrangement as the first set of shapes does not result in a violation when assigned together to one of the separate layouts of a decomposition (whether both sets of shapes are assigned to the same color or to different colors). The context that determines whether such a set of shapes results in a violation or not, in some embodiments, is the surrounding shapes in each region of the design layout. Based on the other surrounding shapes, generating a correct mask design for the first set of shapes may be more difficult (or not possible) than generating a correct mask design for the second set of shapes (e.g., due to interference from the mask shapes needed to correctly print the shapes nearby to the first set of shapes).

It should be noted that the above discussion describes the use of two separate deep learning models—the shape prediction MTN 600 and the violation detection MTN 700. Some embodiments, however, use a single deep learning model (e.g., an MTN such as a convolutional neural network) that effectively combines these two MTNs. Specifically, such a model receives as input a set of multiple separate layouts for a decomposition (i.e., all of the separate layouts of a decomposition) and outputs the set of violations for that input. In such a model, the predicted manufactured layer is not actually generated as this is effectively handled within the deep learning model (though the training of such a model would involve generating predicted manufactured layers in order to perform violation identification).

Returning again to FIG. 2, after determining the violations for the decomposition, the process 200 computes (at 240) a fitness score based on these violations. As described previously, existing measures of decompositions look at the design layout itself (or simply at the graph of design layout features used to perform the decomposition) and identify conflicts as a binary measure. The process 200, on the other hand, uses the violations identified based on the predicted manufactured layer to compute a fitness score for the decomposition.

Different embodiments use different metrics to compute the fitness score. For instance, some embodiments use the number of identified violations throughout the predicted manufactured layer as the fitness score, while other embodiments use the total area of these violations. Still other embodiments use a weighted sum of these two measures, such that (i) fewer violations results in a better fitness score generally but (ii) the size of these violations is a factor (i.e., larger violations are measured as worse than smaller violations). This weighting may be a predefined setting of the layout decomposition tool or may depend on the user (e.g., mask designer) in different embodiments. Yet other embodiments use different metrics based on the violations to generate a fitness score for the decomposition.

The process 200 then determines (at 245) whether to continue optimizing the decomposition. The process 200 is an iterative process that uses the fitness score to measure decompositions (i.e., coloring assignments) and continues attempting to improve the decomposition of a design layout until an end condition is reached. This end condition may be a particular number of iterations or time threshold being reached, a decomposition with a fitness score below a threshold (or above a threshold, depending on the fitness score calculation), or a failure to improve the fitness score after a particular number of iterations.

Assuming the end condition has not been reached, the process modifies (at 250) the decomposition based at least in part on the identified violations to define a new set of two or more separate layouts. In some embodiments, the number of separate layouts (i.e., number of colors) for the design layout is predefined and is the same each iteration. Other embodiments may attempt to optimize the number of separate layouts (e.g., by starting at two colors, then moving to three if an adequate decomposition cannot be reached, then moving to four, etc.).

In some embodiments, the layout decomposition tool generates the new decompositions using a linear programming algorithm (e.g., integer linear programming or mixed-integer linear programming), semidefinite programming, or other heuristics. In some embodiments, the layout decomposition tool specifically focuses on areas that have created violations or regions of the layout with higher rates of violations (or larger violation areas) to attempt to reduce these violations when generating the modified decomposition.

Furthermore, because the fitness score of some embodiments is a continuous function (unlike a simple counting of the number of conflicts, the area component of the fitness score is continuous), some such embodiments use a gradient descent optimization method. In some such embodiments, the process computes the gradient of the fitness score (e.g., with respect to specific color assignments) and uses gradient descent to modify the decomposition (and to ascertain whether certain color assignment modifications have improved the decomposition).

More generally (whether using gradient descent or not), some embodiments use a determination as to whether the previous set of modifications improved or worsened the decomposition to determine whether to keep those modifications and base the next iteration off of the most recent decomposition or try a new set of modifications to the previous decomposition. Some embodiments will at least sometimes keep a set of modifications that worsen the fitness score so as to avoid settling into a local minimum of the fitness score that is not globally optimal. In some such embodiments, the optimization process is more likely to keep modifications that worsen the fitness score early in the optimization as compared to later in the optimization. In addition, some embodiments (especially early in the optimization process) will generate a new decomposition that is not specifically based on the previous decomposition.

After modifying the decomposition, the process 200 returns to 215 to begin the manufactured shape prediction and decomposition scoring process for the new decomposition. As noted, the process 200 continues iterating on the decomposition until an end condition (optimized fitness score, time or iteration limit, etc.) is reached.

Once the process 200 determines that the end condition is reached, the process 200 determines (at 255) whether the design layout should be modified. In some embodiments, whereas the determination at operation 245 as to whether continue optimizing the decomposition is part of the automated decomposition process, the determination as to whether to modify the design layout is a user decision. For instance, a user might identify that a particular group of layout shapes cause violations even in the optimized decomposition, and return to the physical design process to modify the relative locations of the features represented by these layout shapes. In different embodiments, the user might return to various different sub-processes in the physical design process (e.g., floorplanning, placement, routing, compaction). In other embodiments, this decision can be automated based on an assessment of the optimized decomposition.

If the process 200 (i.e., either the user or an automated decision) determines that the design layout should be modified to achieve a better coloring assignment, the process 200 modifies (at 260) the design layout based at least in part on the remaining decomposition violations. As mentioned, this can entail a circuit design returning to any of the physical design processes to adjust the layout of the IC. The process 200 then returns to 205 to begin the layout decomposition process for the updated physical design.

Once the decomposition process is concluded satisfactorily, the process 200 uses (at 265) the current (optimized) decomposition to generate multiple masks for the IC layer, then ends. As described further below, in some embodiments each separate layout is provided to a mask design program (e.g., an optimal proximity correction (OPC) or inverse lithography technology (ILT) tool) that designs an optimal mask for each of the color assignments. These masks are then fabricated according to the optimal mask designs and used in the fabrication of the IC layer.

It should be noted that, in some embodiments, the operations 255-265 are not part of the same automated process as operations 205-250. That is, in some embodiments an automated layout coloring process performs the operations 205-250 until an optimized decomposition is reached, and then a user determines whether to modify the design layout. Once the design layout and decomposition are approved, the multiple separate layouts can be provided to a mask design tool to begin the mask generation process.

In the examples above, the design layout (i.e., each separate color assignment for the design layout) is provided to an MTN. In some embodiments, to format the design layout for input to the MTN, the MTN is rasterized so as to be represented by pixels. Many design layout tools generate the design layout as a set of geometric features (e.g., in a vector format). In some such embodiments, each feature is defined as an ordered set of vertices (e.g., x-y locations) that connect to form the edges of the feature. These geometric features are rasterized in order to prepare the layouts for input to the MTN.

Rasterization of a layout (or portion of a layout) involves transforming the geometric information into a pixel image (a set of pixel values) indicating which of the pixels of the pixel image belong to one of the features for which the mask is to be defined (e.g., an interconnect wire segment, a via or contact, etc.). In some embodiments, this image rasterization produces white pixels for pixels that are fully within a feature, black pixels for pixels that are fully outside of any features, and grey pixels for pixels that are partially covered by a feature. In some such embodiments, the pixels fully covered by features are represented with the numerical value 1.0, the pixels fully outside of the features are represented with the value 0.0, and partially covered pixels are represented with a value in the range [0,1] representative of the area of the pixel which is filled by the feature (e.g., a pixel that is 50% filled will have a value of 0.5).

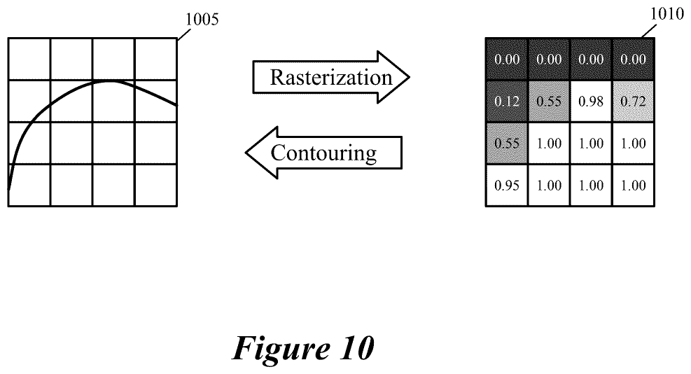

A rasterized layout image is also referred to as a raster tone map (RTM), and the numerical values referred to as raster tone values. An RTM is an image in which the pixel data that is created by rasterization has three kinds of pixels: exterior pixels with a pixel dose value 0, interior pixels with a pixel dose value 1 and edge pixels with pixel dose values greater than 0 and smaller than 1. FIG. 10 illustrates an example of a curved edge of an interconnect segment 1005 that is converted into an RTM 1010 through rasterization.

In some embodiments, edge pixels correspond to the areas where the original geometry data had an edge, and the dose value of any one pixel corresponds to the area of the pixel covered by that geometry data. The accuracy of rasterization depends on the pixel size used for sampling the geometries such that the pixel value indicates the normalized area of the geometry data overlapping the corresponding pixel area. As indicated in FIG. 10, contouring is the opposite process to rasterization. Contouring reconstructs the geometry data from the pixel data.

Instead of RTMs, other embodiments use continuous tone maps (CTMs) or quantized tone maps (QTMs). In such tone maps, the pixel values are in a range that starts below a threshold value and ends above a threshold value. In CTM or QTM, the data typically varies more gradually from pixel to pixel than the rasterized data. Also, in some embodiments of CTM or QTM, the pixels with values below the threshold value are exterior pixels, the pixels with values above the threshold value are interior pixels, and the pixels with values at or near the threshold values are edge pixels. CTM and QTM values are often used when the source of pixel data is computational lithography. QTM values are quantized two-dimensional values of a continuous function and the pixel values do not directly encode the area coverage.

Since both rasterization and contouring operations are computationally intensive, some embodiments stay in the pixel-based computing domain for multiple operations for purposes of efficiency. For instance, some embodiments convert the initial design layout into the pixel domain and then perform all of the other operations (decomposition, manufacturing prediction, violation identification) in the pixel domain (i.e., rather than performing decomposition in the geometry domain and having to convert the violation information back into the pixel domain each iteration). Performing successive computations in the pixel domain enables data to be transferred to GPUs, which tend to be more efficient for pixel-based computations, and then stay on the GPU as the data is transformed (i.e., rather than repeatedly transferring data between a CPU and one or more GPUs).

In the above description relating to FIG. 2, one decomposition is generated at each iteration of the process. The predicted manufactured shapes for that decomposition are simulated, and the decomposition is assigned a fitness score, which is then used to inform the next decomposition. Other embodiments, however, use algorithms that generate numerous different decompositions of the layout at each iteration. For a given iteration, the layout decomposition tool simulates the manufactured shapes for all of the different decompositions and computes fitness scores for each decomposition (e.g., using the techniques described above). The layout decomposition tool then identifies the subset of these decompositions with the best scores (e.g., the top 20%) and uses these to generate the next iteration of decompositions. Each decomposition in a new iteration may be generated by combining multiple different decompositions from the top-scoring subset (using a “genetic’ algorithm) or by randomly modifying individual decompositions from the top-scoring subset (using an “evolutionary” algorithm). For instance, in the latter case, if one thousand new decompositions are generated each iteration, then the best two hundred decompositions in one iteration can be used to each generate five new decompositions for the next iteration (by applying five different sets of random color assignment changes to each of the top-scoring decompositions).

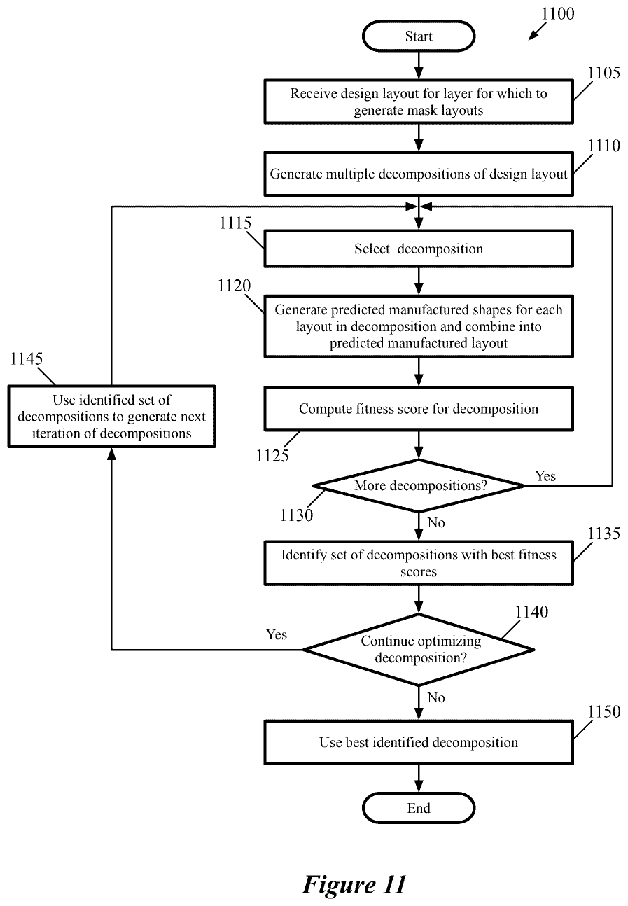

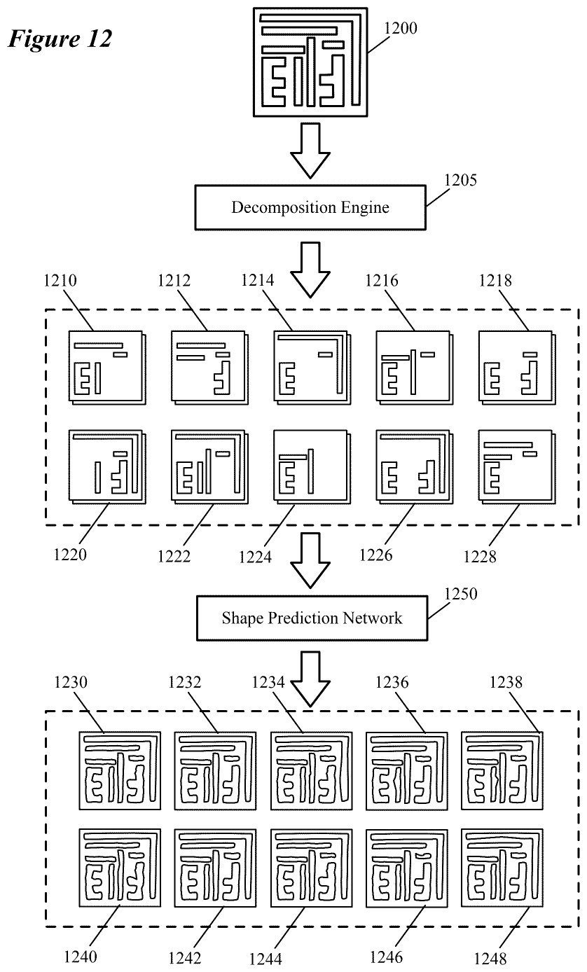

FIG. 11 conceptually illustrates a process 1100 of some embodiments for optimizing a design layout decomposition using an iterative process that generates numerous different decompositions each iteration. The layout decomposition process 200 of some embodiments may be performed by a layout decomposition tool, which may be a part of a mask design tool (e.g., within a larger electronic design automation (EDA) process) or a separate tool that is used prior to mask design. The process 200 will be described in part by reference to FIGS. 12-14, which illustrate examples of such an iterative process.

As shown, the process 1100 receives (at 1105) a design layout for a layer (e.g., for a layer of an IC) for which to generate mask layouts. The design layouts of some embodiments include numerous features, or shapes. These features represent layer components, such as interconnect (wiring) segments for a metal (wiring) layer, via holes for a via layer, etc. The design layout may restrict features to specific angles or allow an omnidirectional set of features. Common design layouts with the features restricted to certain angles include Manhattan layouts (i.e., with all of the features arranged either horizontally or vertically) or layouts allowing specific diagonal angles (e.g., features arranged horizontally, vertically, and at 45° angles). Other layouts include omnidirectional rectilinear layouts (i.e., layouts with entirely straight lines but at any angle) as well as curvilinear layouts (i.e., layouts in which some of the features may have curved edges). For ICs, the received design layout is typically the output of a physical design process that includes operations such as floorplanning, placement, routing, and compaction (and has often been verified by a layout verification tool).

The process 1100 then generates (at 1110) multiple decompositions of the design layout. The number of different decompositions may vary in different embodiments, from a small number such as 5 or 10 to larger numbers such as 100, 1000, or more. Different embodiments may use different techniques for generating the initial decomposition options. As described in more detail below, in some embodiments an MTN or other deep learning model generates decompositions. Other embodiments use graph-based techniques, in which each of the features is assigned as a node in a graph and two features that are within a threshold distance are connected as nodes. If no cycles of three or more nodes exist, then decomposition into two layouts is relatively simple. However, in a typical IC layer, many such cycles exist and identifying a solution with no conflicts is an NP-hard problem. As such, some embodiments perform an initial assignment either randomly or by stepping through the graph in order and assigning nodes to different colors in a next neighbor manner. Some embodiments use a non-deterministic method or a deterministic method with randomized starting points so as to generate many different decompositions for the same design layout.

FIG. 12 conceptually illustrates the generation of ten different decompositions of a design layout 1200. It should be understood that a design layout with only eight shapes could likely be decomposed (if even necessary) into two different layouts by manual user input, but that this is representative of processes applied to much larger design layouts (e.g., with thousands or millions of different features). The design layout 1200 is provided to a decomposition engine 1205 that generates ten different decompositions 1210-1228 of the design layout 1200. Each of these decompositions 1210-1228 is different from all of the others by at least one shape's color assignment.

The process 1100 then scores each of the multiple decompositions. Specifically, the process 1100 selects (at 1115) one of the decompositions. It should be understood that the process 1100 is a conceptual process and that the process does not evaluate each individual decomposition separately in some embodiments. Rather, the layout decomposition tool, in some embodiments, performs operations in parallel for some or all of the separate decompositions.

The process 1100 generates (at 1120) the predicted manufactured shapes for each layout in the decomposition and combines these into a predicted manufactured layout. As described above by reference to FIG. 2, the generation of these predicted manufactured shapes for a given layout may be performed by providing the layout to a shape prediction MTN in some embodiments. FIG. 12 illustrates how each of the decompositions 1210-1228 (i.e., each layout in each of these decompositions) is provided to a shape prediction network 1230, resulting in ten different predicted manufactured layers 1232-1250.

Next, the process 1100 computes (at 1125) a fitness score for each of the decompositions. As described above, in some embodiments this entails providing each predicted manufactured layer to a violation identification MTN to determine manufacturability violations and then using these manufacturability violations to compute the fitness score. Different embodiments use different metrics to compute these fitness scores. For instance, some embodiments use the number of identified violations throughout the predicted manufactured layer for a decomposition as the fitness score for that decomposition, while other embodiments use the total area of these violations. Still other embodiments use a weighted sum of these two measures, such that (i) fewer violations for a decomposition results in a better fitness score generally but (ii) the size of these violations is a factor (i.e., larger violations are measured as worse than smaller violations). This weighting may be a predefined setting of the layout decomposition tool or may depend on the user (e.g., mask designer) in different embodiments. Yet other embodiments use different metrics based on the violations to generate fitness scores for the decompositions.

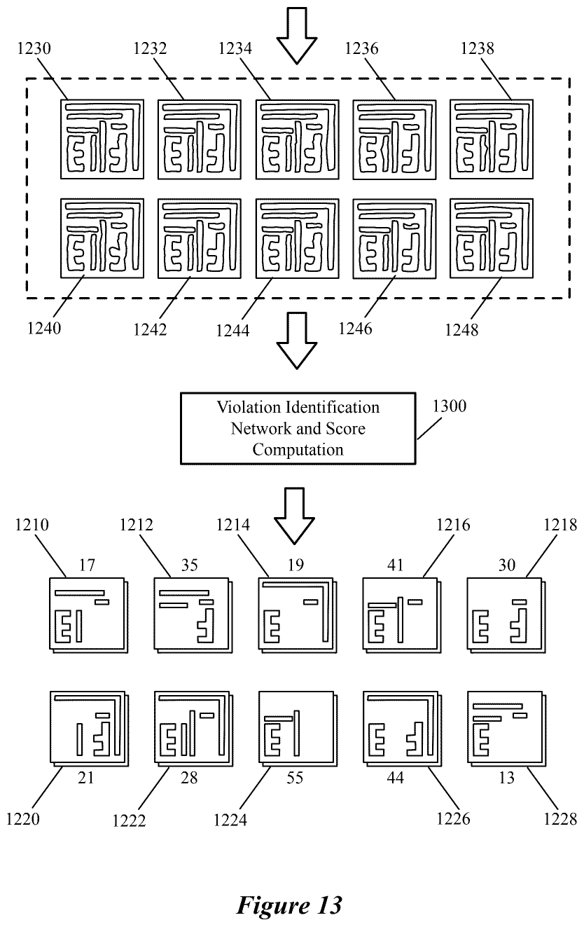

FIG. 13 conceptually illustrates the generation of fitness scores for each of the predicted layers 1230-1248 (corresponding to the decompositions 1210-1228). As shown, each of the predicted layers 1230-1248 is provided to a violation identification network 1300 that identifies violations in the predicted layers resulting from the decomposition. Fitness scores are generated based on each of these sets of violations and are shown along with each of the decompositions 1210-1228). In this case the fitness scores range from 13 (for decomposition 1228) to 55 (for decomposition 1224), with smaller numbers representing fewer/smaller violations. It should be noted that while in this case all of the fitness scores are integers, this is not necessary, and these are meant to represent relative scores. Scores that incorporate violation area especially will not necessarily result in integer values.

After computing the fitness score for the selected decomposition, the process 1100 determines (at 1130) whether additional decompositions remain. If additional decompositions require fitness scores, the process 1100 returns to 1115 to generate the predicted layer for the next decomposition and assign a score to that decomposition, until all of the decompositions have been assigned fitness scores.

The process 1100 then identifies (at 1135) the set of decompositions with the best fitness scores. These may be the lowest or highest fitness scores, depending on how the scores are computed. In addition, different embodiments select different percentages of the decompositions. For instance, some embodiments identify only the one best decomposition while other embodiments identify the top 5%, 10%, 20%, etc. of the decompositions generated for the current iteration.

Next, the process 1100 determines (at 1140) whether to continue optimizing the decomposition. The process 1100 is an iterative process that uses the fitness scores to measure multiple decompositions (i.e., coloring assignments) per iteration and continues attempting to improve the decomposition of a design layout until an end condition is reached. This end condition may be a particular number of iterations or time threshold being reached, a decomposition with a fitness score below a threshold (or above a threshold, depending on the fitness score calculation), or a failure to improve the fitness scores after a particular number of iterations.

Assuming the end condition has not been reached, the process uses (at 1145) the identified set of decompositions with the best fitness scores to generate the next iteration of decompositions. As will be described further below, other embodiments use a varied set of decompositions to generate the next set of decompositions (e.g., not only the best scoring decompositions). Specifically, to generate the next set of decompositions, some embodiments use a genetic or evolutionary algorithm. For instance, some embodiments use a genetic algorithm that uses two or more of the selected (best scoring) decompositions to generate each of the next set of decompositions. Other embodiments use an evolutionary algorithm that applies modifications (“mutations”) to each of the selected decompositions to generate the next set of decompositions.

As an example for a genetic algorithm, a particular iteration of the process 1100 might have one thousand different decompositions, two hundred of which are selected as the best scoring options for that iteration. To generate the next set of decompositions, some embodiments might identify one hundred pairs of decompositions from the selected two hundred. For each such pair of “parents”, the layout decomposition tool then generates five new decompositions by combining characteristics of the parents (e.g., keeping all of the coloring assignments that are the same between the two parents but randomly selecting between the coloring assignments where the two parents differ. Other such embodiments identify more pairs of decompositions and generate fewer new decompositions per pair (e.g., one thousand different pairs with each decomposition belonging to five different pairs and then generating one new decomposition per pair), or identify larger groups of decompositions and combine these in different ways (e.g., identifying groups of three and generating new decompositions based on the coloring assignments for each shape found in the majority of the group).

For evolutionary algorithms, a particular iteration of the process 1100 could also have one thousand different decompositions with two hundred selected. To generate the next set of decompositions, in this case, each of the selected decompositions is “mutated” to generate five new decompositions for the next iteration. These mutations, in some embodiments, involve reassignment of a subset of the features of the design layout to a different color. Some embodiments reassign a random set of features while other embodiments base the mutations on the location of violations in the decomposition (e.g., a random selection of the features the color assignments of which seem to most contribute to the violations).

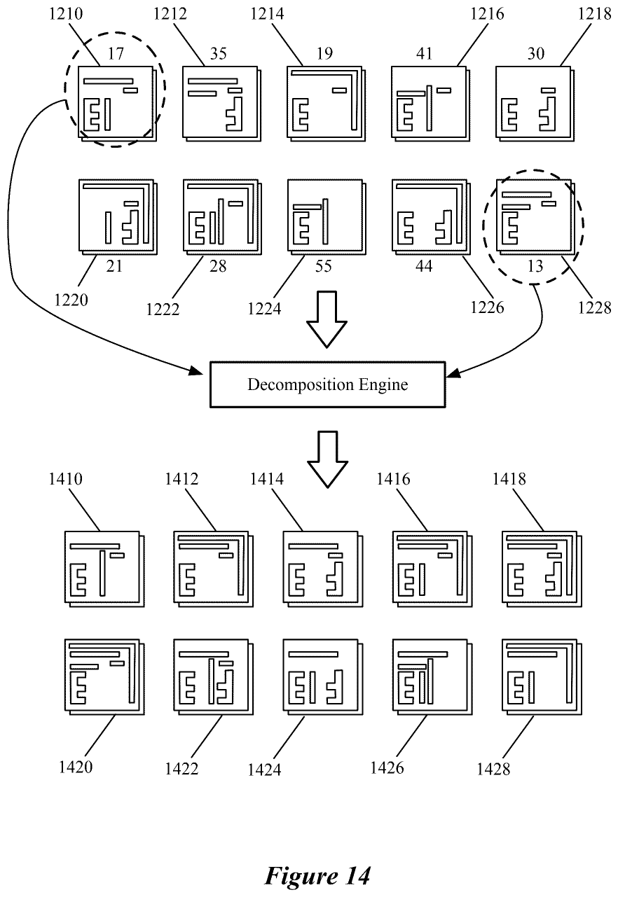

For instance, FIG. 14 conceptually illustrates a generation of ten new decompositions based on the best scoring of the previous decompositions 1210-1228. As shown, the decompositions 1210 and 1228 have the lowest (best) scores and are thus provided to the decomposition engine 1205. The decomposition engine 1205 generates ten new decompositions 1410-1428, with five of these new decompositions based on the decomposition 1210 and the other five based on the decomposition 1228. It should be noted that due to the simplicity of the example having only eight features, many of the decompositions will appear very similar, whereas a more realistic scale design layout will have significantly greater differentiation between decompositions owing to the much larger number of features.

Returning again to FIG. 11, the process 1100 continues generating numerous new decompositions at each iteration (based on the best scoring decompositions from the prior iteration) until an end condition is reached. Once an end condition (fitness score below/above a threshold, time or iteration threshold reached, etc.), the process 1100 uses (at 1150) the best identified decomposition as the coloring assignment for the design layout. In some embodiments, this is the best scoring decomposition from the last iteration, while in other embodiments the process uses the best scoring decomposition from any iteration (which will often, but not necessarily, be the last decomposition).

As noted, while the process 1100 uses the best-scoring decompositions at each iteration to generate the next group of decompositions, other embodiments use other approaches. For instance, rather than only use the top X % (e.g., 5%, 10%, 20%, etc.) of the decompositions in one iteration as the seeds for the subsequent iteration, some embodiments implement various heuristics to ensure that some lower-scoring decompositions are selected. It is possible that certain decompositions with lower scores are actually more likely to be the starting point for better decompositions after several additional iterations. Thus, for instance, some embodiments randomly select the decompositions for the next iteration but use weighting so that the best-scoring decompositions are more likely to be selected. As an example, some embodiments use a first weighting for the top X % scoring decompositions and a second (lower-likelihood) weighting for the remaining decompositions. Other embodiments assign weights that are either inversely or directly proportional to the actual fitness scores (depending on whether the better fitness scores are lower or higher), so that the likelihood of selecting a decomposition as a seed for the next iteration increases as the score for that decomposition improves. Still other embodiments employ a cutoff below which the weighting (likelihood of selection) becomes zero (e.g., only the top 50% of decompositions are selectable).

Irrespective of the manner of selection of the decompositions, some embodiments also do not only generate modified decompositions for a subsequent iteration. That is, some embodiments select a particular number of decompositions (e.g., 200 out of 1000), then use these directly as part of the next iteration of decompositions. For instance, taking the example described above, for a subset of the 200 selected decompositions, the process could generate four new decompositions and also re-use the selected decomposition. These decompositions that are directly included in the next iteration could be the best-scoring decompositions or randomly chosen from the selected decompositions, in different embodiments.

As described above, in some embodiments a user can determine whether to use the optimized decomposition that results from the process 1100 (or one of its variations) or modify the physical design layout (e.g., to modify areas of the physical design that are creating difficulties for the decomposition. If the user is okay with the decomposition and does not need to modify the physical design, then the decomposition can be used for mask generation. As described further below, in some embodiments each separate layout of this decomposition is provided to a mask design program (e.g., an optimal proximity correction (OPC) or inverse lithography technology (ILT) tool) that designs an optimal mask for each of the color assignments. These masks are then fabricated according to the optimal mask designs and used in the fabrication of the IC layer.

Whether generating a single decomposition or multiple decompositions per iteration, the processes described above use a fitness score based on the predicted manufactured shapes for the layer being decomposed. However, some embodiments additionally factor in other (e.g., neighboring) layers of the IC design when computing the fitness score for a decomposition. Thus, for instance, the fitness score for the decomposition of a particular metal (wiring) layer might factor in the relation of the metal layer to the neighboring z-axis connection (e.g., via and/or contact) layers and/or the metal layers above or below that layer, in addition to the manufacturability of the layer itself owing to the decomposition. Specifically, some embodiments factor in the overlap of components of the current layer (i.e., the layer being evaluated) with components in the neighboring layers, such as wire ends overlapping with vias (a common type of overlap).

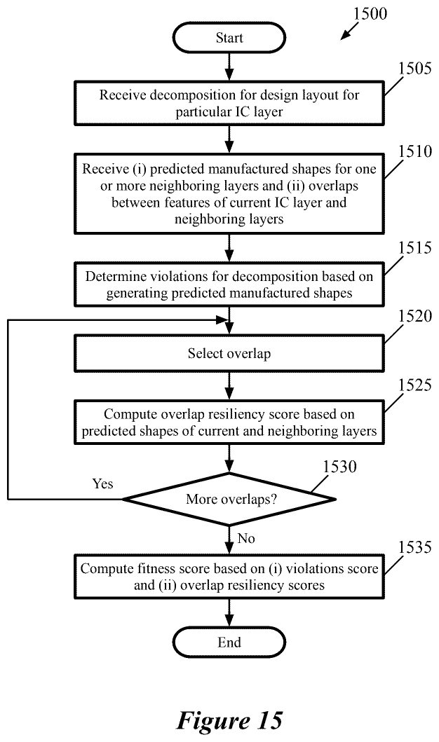

FIG. 15 conceptually illustrates a process 1500 of some embodiments for computing a fitness score for a decomposition of a design layout for a first layer using both manufacturability violations for the first layer as well as the interaction of the first layer with at least one additional layer. The process 1500 is performed, in some embodiments, by a layout decomposition tool, which may be a part of a mask design tool (e.g., within a larger electronic design automation (EDA) process) or a separate tool that is used prior to mask design. In some embodiments, the process 1500 may be used to compute the fitness scores for each decomposition within an iterative process such as those shown in FIGS. 2 and 11.

As shown, the process 1500 begins by receiving (at 1505) a decomposition for a design layout for a particular IC layer. The decomposition may have been generated in the manner described above (e.g., using a graph coloring technique) and may be an initial decomposition (or one of an initial group of compositions) or a decomposition further along in one of the iterative processes. The design layout, as described previously, includes numerous features representing layer components, and these features may be restricted in their shape and orientation or can be omnidirectional and/or curvilinear.

The process 1500 also receives (at 1510) both (i) predicted manufactured shapes for one or more neighboring layers of the design layout and (ii) overlaps between the features of the particular IC layer and the neighboring layers. For instance, if the layer for which the decomposition analysis is being performed is a metal layer, some embodiments include at least the predicted manufactured shapes for the via or contact layers (i.e., the dielectric layers) on either side of that metal layer. If a via traverses through multiple layers, some embodiments may include all of these layers as neighboring layers. In addition, some embodiments include metal layers on either side of the current metal layer as neighboring layers. If the layer for which the decomposition analysis is being performed is a via layer, some embodiments include at least the predicted manufactured shapes for the metal layers on either side of that via layer. If the via layer includes vias traversing through multiple layers, some embodiments may include all of these layers as neighboring layers.

Some embodiments specify a set of overlaps of features in the current IC layer and features in the other layers. For instance, a common type of overlap is a via or contact (i.e., a z-axis connection through a dielectric layer) that is meant to intersect a line end (i.e., an interconnect wiring segment) within a metal layer. When assessing the manufacturability of a decomposition for a particular layer, it can be important to ensure not only that the particular layer will be manufacturable but also that the manufactured layer will properly connect to other layers (especially in a manner that is resilient to manufacturing variation), as these connections are critical to the proper functioning of the IC. Thus, for a metal layer some embodiments specify all of the line ends of the layer that overlap with vias in the layer above and/or below, while for a via layer some embodiments specify all of the vias that overlap with line ends in the metal layers above and/or below. In addition to overlaps of line segments with vias, the overlaps may include vias overlapping with metal segments other than line ends (e.g., plates of a capacitor), overlap between capacitive plates in two subsequent metal layers, and other types of overlap.

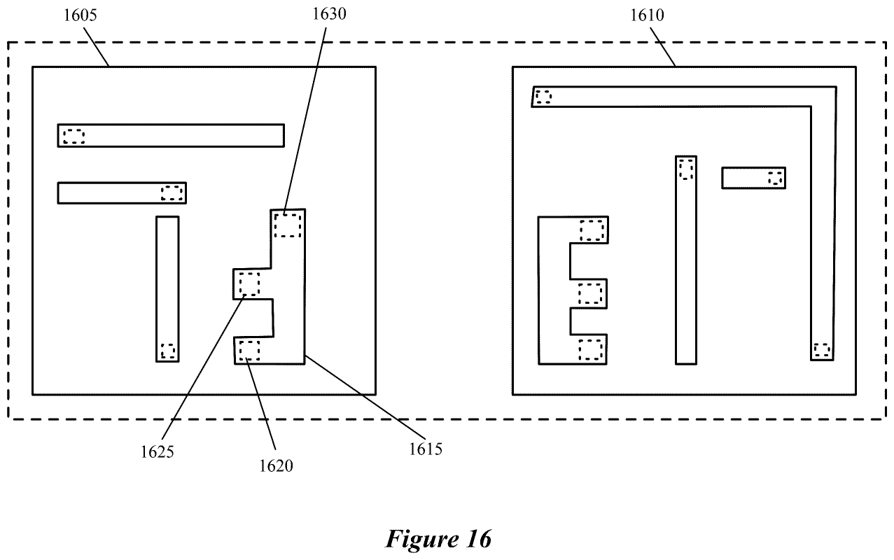

FIG. 16 conceptually illustrates an example of a decomposition 1600 for a portion of a first (metal wiring) layer with overlaps between the features of the first layer and features of other layers. As shown, the decomposition 1600 includes two separate layouts 1605 and 1610, each with multiple features representing interconnect wiring segments. Each of these features includes multiple overlaps with features of neighboring layers (in this case vias belonging to via layers), which are shown using dotted lines. As an example, the feature 1615 in the first layout 1605 of the separate layouts has three feature overlaps 1620-1630, while each of the other features in the separate layouts 1605 and 1610 has at least one feature overlap.

The process 1500 then determines the violations for the decomposition based on generating the predicted manufactured shapes. In some embodiments, these violations are the violations described above (e.g., by reference to FIGS. 2 and 7-9). As described above, some embodiments provide the multiple separate layouts of the decomposition to a shape prediction MTN, then provide the predicted manufactured layer to a violation detection MTN in order to identify the violations for the decomposition.

The process 1500 can then compute a fitness score using both the violations as well as the overlap information. As shown, the process 1500 selects (at 1520) one of the overlaps of a feature in the current layer and a feature in another layer. It should be understood that the process 1500 is a conceptual process and that the layout decomposition tool of some embodiments performs computations in parallel for multiple overlaps between current-layer and neighboring-layer features.

The process computes (at 1525) an overlap resiliency score based on the predicted shapes of the current and neighboring layers. Referring to the example of FIG. 16, a resiliency score is computed for each of the indicated overlaps in each of the separate layouts 1605 and 1610. Different embodiments may compute these overlap resiliency scores using different techniques. Some of these techniques are described in greater detail in the context of optimizing a mask design in U.S. patent application Ser. No. 18/814,426, entitled “Mask Optimization for First Layer That Accounts for Other Layers”, which is incorporated herein by reference. These techniques are also applicable to computing scores for the purpose of optimizing a decomposition.

For instance, one such technique entails computing the area of overlap between each pair of predicted manufactured shapes (i.e., one shape in the current layer and one shape in a neighboring layer) and assigning a resiliency score based on this area. In general, a larger area of overlap is better and can be assigned a higher or lower resiliency score depending on how the resiliency score is incorporated into the overall fitness score.

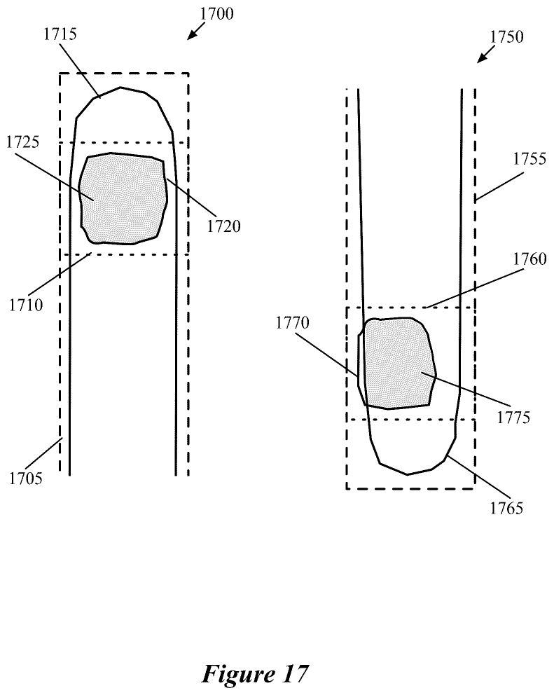

FIG. 17 conceptually illustrates an example of the overlap resiliency for two different overlaps 1700 and 1750 between predicted manufactured shapes. Both of these examples involve the intersection of an interconnect segment line end and a via. The first overlap 1700 shows the design layout shapes for the line end 1705 and the via 1710, in addition to the predicted manufactured shapes for the line end 1715 and the via 1720. Similarly, the second overlap 1750 shows the design layout shapes for the line end 1755 and the via 1760, in addition to the predicted manufactured shapes for the line end 1765 and the via 1770.

The overlap resiliency calculations may be performed for either a metal layer to which the interconnect segments belong or a dielectric layer to which the vias belong (or for multiple layers if optimizing decompositions of multiple layers simultaneously). When optimizing decomposition for a metal layer, both of the line ends 1705 and 1755 would be in the same layer while the vias 1710 and 1760 could be in the same or different layers. That is, if optimizing metal layer 3, then the via 1710 could connect the first line end 1705 to an interconnect in metal layer 2 (or a lower layer) while the other via 1760 could connect the second line end 1755 to an interconnect in metal layer 4 (or a higher layer). On the other hand, if optimizing decomposition for a via layer, both of the vias 1710 and 1760 would be in the same layer while the line ends 1705 and 1755 could be in the same or different layers.

The figure additionally shows that the overlap 1700 has a larger area of intersection 1725 between the predicted line end shape 1715 and the predicted via shape 1720 compared to the area of intersection 1775 between the predicted line end shape 1765 and the predicted via shape 1770. As a result of the current decomposition, the second predicted via shape 1770 is smaller than the first predicted via shape 1720 and is also misaligned with its corresponding line end 1765. Given this, the resiliency score for the first overlap 1700 would be better (either higher or lower, depending on how the resiliency score is used within the overall fitness score) than the resiliency score for the second overlap.

To compute this area of intersection (the overlap, or cross-sectional overlap) between a first predicted shape in the current layer and a second predicted shape in another layer, some embodiments use the rasterized predicted manufactured layer images. The generation of the predicted manufactured layer image for the current layer (i.e., the layer being optimized) is described in detail above. For the other layers, if the decomposition has been performed already for these layers, then some embodiments use this decomposition to generate the predicted manufactured layer images for the other layers (e.g., using the same type of MTN described above). If no decomposition has been performed for one of the other layers, some embodiments use an MTN to generate the predicted manufactured layer images for these other layers (e.g., an MTN that treats the layer as being fabricated using a single mask). Other embodiments use a corner rounding algorithm (e.g., a low pass filter and/or Gaussian convolution) to generate the predicted manufactured wafer images for these other layers.

To perform the area computation, some embodiments multiply the pixel value of each pixel in the region of the predicted manufactured IC layer image (i.e., in the region of the overlap for which the area of intersection is computed) with the pixel value for the equivalent pixel (i.e., having the same coordinate in the x-y plane) in the other layer. Thus, coordinates that are in the interior region of both shapes will have a value of 1.0 (1.0×1.0) and coordinates that are on the exterior of either shape will have a value of 0.0 (0.0×any pixel value). Pixels along the contour of one or both shapes will have a smaller value, with at least one of the pixel values being in the range (0, 1). A coordinate that is fully within one of the shapes but is an edge pixel for the other shape will have the value of the pixel value of the other shape, because that value is multiplied by 1.0. Coordinates that are on the edge of both shapes can have those two values multiplied; to the extent the multiplication of the pixel values of these overlapping edge pixels does not exactly represent the area of intersection, the error introduced is typically minimal on the scale of the entire shape. Other embodiments, rather than multiply the edge pixels together, take the average of the two pixel values or perform another calculation using these values.

Some embodiments also initially compute the area for each overlap and then compute normalized resiliency scores that are scaled to vary between the values of 0 and 1. For example, in FIG. 17, the first overlap 1725 is in some embodiments assigned a resiliency score closer to 1.0 while the second overlap 1775 is assigned a resiliency score closer to zero. In other embodiments, a score closer to 1.0 indicates less resiliency while a score closer to zero indicates greater resiliency (e.g., as the goal is to minimize the scores within the loss function).

As described in greater detail in U.S. patent application Ser. No. 18/814,426, which is incorporated by reference above, some embodiments use multiple different predicted manufactured layer images for each layer in the computations. Specifically, some embodiments determine the overlap area of two predicted manufactured shapes over various different manufacturing conditions and then determine the intersection of all of these overlaps (i.e., the polygon that is part of all of the individual two-component intersections). These various manufacturing conditions include different process conditions (e.g., minimum, nominal, and maximum) that can result in smaller or larger feature shapes as well as misalignment in different directions (e.g., left, right, up, down).

Some embodiments consider each combination of (i) misalignment direction (or no misalignment) and (ii) process condition set and determine the intersection polygon of the two components for each of these combinations, then determine the overall intersection of these intersection polygons as the overall resiliency polygon. For instance, some embodiments consider three different sets of process conditions and four different misalignment directions for each set of process conditions, for a total of twelve intersection polygons between a given pair of components. The area of the resulting overlap is then indicative of the resilience of the associated pair of components to coverage-related issues in the presence of manufacturing variations and misalignments. Other embodiments, however, only compute a single intersection area based on one predicted layer image for each layer. Some such embodiments rely on the mask design process to handle resiliency to manufacturing conditions.

Returning to FIG. 15, the process 1500 then determines (at 1530) whether additional overlaps remain for which the resiliency scores need to be calculated. If such additional overlaps remain, the process 1500 returns to 1520 to select the next overlap and compute a resiliency score. Some embodiments perform these intersection calculations (or other overlap resiliency score calculation) for each pair of overlapping (intersecting) features in the current layer and any other layer.

Once the resiliency scores have been computed for all of the overlaps, the process 1500 computes (at 1535) a fitness score based on (i) a violation-based score and (ii) the overlap resiliency scores, and ends. In some embodiments, this fitness score is a weighted sum of a violation component and an overlap component. For instance, the following provides an example of such a fitness score:

$$L = {w}_{v} ( {w}_{N} {N}_{v} + {W}_{A} \sum {A}_{n} ) + {w}_{o} \sum {W}_{i} {O}_{i}$$

In this fitness score equation, the weights wᵥ and wₒ weight the violation and overlap scores respectively. The violation score is a weighted sum of the number of violations Nᵥ and the combined areas Aₙ of the violations. The overlap score is a weighted sum of the individual resiliency scores Oᵢ for each designated overlap. It should be noted that some embodiments set the individual weights wᵢ to 1 (i.e., weight all of the overlaps equally), while other embodiments allow users to weight some overlaps as more important than others. In this example, the resiliency scores Oᵢ are lower to indicate larger area and the layout decomposition tool attempts to minimize the overall fitness score L. As described above, this fitness score can be incorporated into the optimization processes described by reference to FIG. 2 or 11.

The fitness score described above relates to optimizing the decomposition for one layer while incorporating information relating to other layers (i.e., how the features in the first layer overlap with features in the other layers). Some embodiments optimize the decompositions for multiple layers at once (e.g., one metal layer and the via layers on either side of the metal layer, one via layer and the metal layers on either side of that via layer, more than three neighboring layers, etc.). In this case, the predicted manufactured shapes for each of these layers are generated for a given iteration based on the decompositions for the layers. Some such embodiments use separate fitness scores for each layer that account for the single-layer manufacturability violations (computed as described above) and any overlaps involving features in the layer. Other embodiments, however, use a single fitness score that accounts for the total violations across all of the layers as well as all of the overlaps involving any of the layers being optimized.

As described above, some embodiments use one or more MTNs to evaluate each decomposition (e.g., a shape prediction MTN and a violation identification MTN). Both of these MTNs, in some embodiments (as well as the MTN used to perform coloring, described below), may be convolutional neural networks (e.g., feed-forward convolutional neural networks) or other types of neural networks. The MTNs of some embodiments receive input data and process that input data through an input layer, one or more hidden layers, and an output layer. Each layer, in some embodiments, includes multiple nodes (neurons) that receive input data from a previous layer, apply a set of parameters (weights) to that data, and generate an output. In some such embodiments, each node includes a linear function (e.g., a dot product of input values and weights, potentially including addition of a bias value after the dot product) followed by a non-linear activation function applied to the output of the node's linear function. In some embodiments, a subset of the hidden layers are convolutional layers. Each convolutional layer receives input values as a set of input channels and convolves a set of filters (groups of weights) over these input channels to compute a set of output values that are arranged in output channels (with the number of output channels equal to the number of filters in the layer). The parameters of these layers (e.g., the weight and/or bias values) are trainable in some embodiments. To use these MTNs (or other deep learning models) at inference time to evaluate a decomposition, the MTNs need to be trained using useful data (e.g., actual coloring assignments for design layouts and actual or simulated manufactured layers for those layouts).

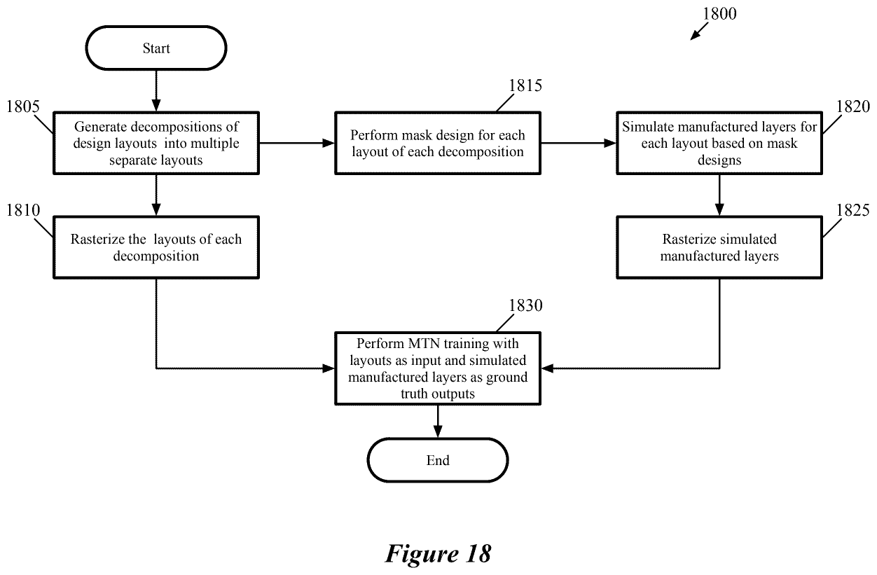

FIG. 18 conceptually illustrates a process 1800 of some embodiments for creating training data and using this training data to train a shape prediction MTN. This process 1800 generates known inputs (coloring assignments of design layouts for which masks are designed) as well as corresponding ground truth outputs (simulated manufactured shapes) for these inputs. In some embodiments, the process 1800 is performed outside of the layout decomposition tool (e.g., by a separate training process) so that the trained MTN can be used by such a tool.

As shown, the process 1800 generates or receives (at 1805) decompositions of design layouts into multiple separate layouts (i.e., coloring assignments for design layouts). These decompositions can include numerous different coloring assignments for a single design layout, one decomposition for each of numerous design layouts, and/or numerous different coloring assignments for each of numerous design layouts. The decompositions can include optimized coloring assignments (i.e., to be actually used for fabricating masks for a design) as well as non-optimal coloring assignments (e.g., randomized coloring assignments). Some embodiments randomly generate design layouts rather than requiring that the inputs actually be coloring assignments.

The process 1800 then splits into two sub-processes. The first sub-process includes operation 1810 that generates the known inputs for the MTN training, while the second sub-process includes operations 1815-1825 to generate the corresponding ground truth outputs. Specifically, the process 1800 rasterizes (at 1810) the layouts of each decomposition. That is, for each separate layout of a decomposition, a rasterized layout is generated. MTNs (e.g., convolutional neural networks) often receive pixel images as input and manipulate these pixel values, so rasterizing the layouts enables the layouts to be used as input data. The rasterization process that converts geometric data into pixel data for a set of shapes (e.g., of a design layout) is described above.

The process 1800 also performs (at 1815) mask design for each separate layout of each decomposition. In some embodiments, the mask design process is performed using an optical proximity correction (OPC) or inverse lithography technology (ILT) tool. These tools are EDA programs that receive a design layout as input and perform an iterative process to optimize a mask design for fabricating an IC layer based on that design layout. ILT tools, for instance, iteratively use lithographic simulation to simulate a wafer image based on a mask design, compare that simulated wafer image to a target wafer image, and use the comparison to adjust the mask design.

Next, the process 1800 simulates (at 1820) the manufactured layers for each layout based on the mask design. Some embodiments use the ILT tool to perform these simulations. As mentioned, the ILT tools of some embodiments perform lithographic simulation operations at each iteration to simulate the manufactured shapes that would be fabricated using a current mask design. This includes simulating the manufactured layer for the final mask design. Other embodiments use a previously trained MTN to simulate the manufactured layer for each layout based on the mask design. Each simulated manufactured layer corresponds to one of the separate layouts of a specific decomposition.

The process 1800 then rasterizes (at 1825) the simulated manufactured layers. That is, for each simulated manufactured layer, a rasterized simulated layer is generated. The rasterization process that converts geometric data into pixel data for a set of shapes (e.g., of a design layout) is described above. These rasterized simulated manufactured layers, each of which corresponds to a separate layout, are used as ground truth outputs for the MTN.

Finally, the process 1800 performs (at 1830) MTN training with the separate rasterized layouts as input and the rasterized simulated manufactured layers as the corresponding ground truth outputs. To train the network, some embodiments propagate batches of known inputs (the rasterized layouts) through the MTN to generate outputs (predicted manufactured layers) for each input. The training process then compares these generated outputs to the ground truth outputs (i.e., compares the predicted manufactured layers to the simulated manufactured layers) to compute error values for each input. These error values are used to compute the value of a loss function (e.g., a cross-entropy loss function), in some cases in conjunction with other loss function terms (e.g., regularization terms, etc.). This loss function is backpropagated through the MTN to compute gradients for configurable parameters (e.g., weight values, bias values, etc.) and adjust these configurable parameters. Some embodiments perform this process iteratively (e.g., using a batch of inputs for each iteration) until the MTN is adequately trained.

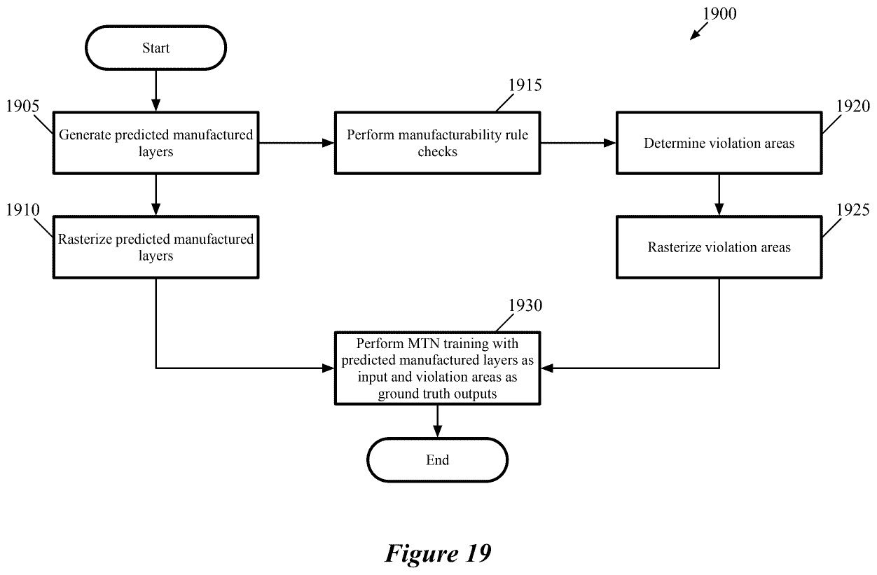

FIG. 19 conceptually illustrates a process 1900 of some embodiments for creating training data and using this training data to train a violation identification MTN. This process 1900 generates known inputs (predicted manufactured layers) as well as corresponding ground truth outputs (violation areas) for these inputs. In some embodiments, the process 1900 is performed outside of the layout decomposition tool (e.g., by a separate training process) so that the trained MTN can be used by such a tool.

As shown, the process 1900 generates or receives (at 1905) predicted manufactured layers. These predicted manufactured layers can be the ground truth outputs used for the network training process 1800 described above, can be simulated layers generated by an ILT program, can be randomly generated manufactured layers, or can be generated in any other manner. In some embodiments, the predicted manufactured layers need not be the result of decompositions.

The process 1900 then splits into two sub-processes. The first sub-process includes operation 1910 that generates the known inputs for the MTN training, while the second sub-process includes operations 1915-1925 to generate the corresponding ground truth outputs. Specifically, the process 1900 rasterizes (at 1910) the predicted manufactured layers. That is, for each predicted manufactured layer, a rasterized predicted manufactured layer is generated. MTNs (e.g., convolutional neural networks) often receive pixel images as input and manipulate these pixel values, so rasterizing the predicted layers enables the predicted layers to be used as input data. The rasterization process that converts geometric data into pixel data for a set of shapes (e.g., of a design layout) is described above.

The process 1900 also performs (at 1915) manufacturability rule checks for each predicted manufactured layer. In some embodiments, these manufacturability rule checks use known manufacturability rule check techniques. These manufacturability rule checks can use various geometric techniques, equation-based techniques, circle tracing, or other techniques, some of which are described in U.S. Patent Publication 2023/0267265, which is incorporated herein by reference.

Based on these rule checks, the process 1900 determines (at 1920) the violation areas for each predicted manufactured layout. In some embodiments, these violation areas are polygons (e.g., similar to the polygons shown in FIGS. 7 and 8). Each set of violation areas corresponds to one of the predicted manufactured layers.

The process 1900 then rasterizes (at 1925) the violation areas (e.g., each set of violation areas corresponding to a predicted manufactured layer). That is, for each set of violation areas (e.g., set of polygons), a rasterized set of violation areas is generated. The rasterization process that converts geometric data into pixel data for a set of shapes (e.g., of a design layout) is described above. These rasterized sets of violation areas, each of which corresponds to a separate predicted manufactured layer, are used as ground truth outputs for the MTN.

Finally, the process 1900 performs (at 1930) MTN training with the rasterized predicted manufactured layers as input and the rasterized sets of violation areas as the corresponding ground truth outputs. To train the network, some embodiments propagate batches of known inputs (the rasterized predicted manufactured layers) through the MTN to generate outputs (predicted sets of violation areas) for each input. The training process then compares these generated outputs to the ground truth outputs (i.e., compares the predicted sets of violation areas to the sets of violation areas generated by manufacturability rule checks) to compute error values for each input. These error values are used to compute the value of a loss function (e.g., a cross-entropy loss function), in some cases in conjunction with other loss function terms (e.g., regularization terms, etc.). This loss function is backpropagated through the MTN to compute gradients for configurable parameters (e.g., weight values, bias values, etc.) and adjust these configurable parameters. Some embodiments perform this process iteratively (e.g., using a batch of inputs for each iteration) until the MTN is adequately trained.

In the above description, the actual generation of a decomposition is performed using various methods such as assignment of nodes in a graph to different colors (i.e., different separate layouts). Some embodiments instead use a deep learning model (such as an MTN) to perform the decomposition. In this case, the deep learning model receives a layout for a layer (or a portion of such a layer) and outputs assignment of the features of that layout to multiple colors. The training data for such a deep learning model may be the design layouts described above (as inputs) and the optimized coloring assignments generated using the above process in some embodiments. Similarly, some embodiments use an MTN or other deep learning model to perform the actual mask design (e.g., rather than an OPC or ILT process). It should be understood that while the discussion herein primarily references MTNs such as convolutional neural networks, other types of deep learning models may be used in some embodiments.

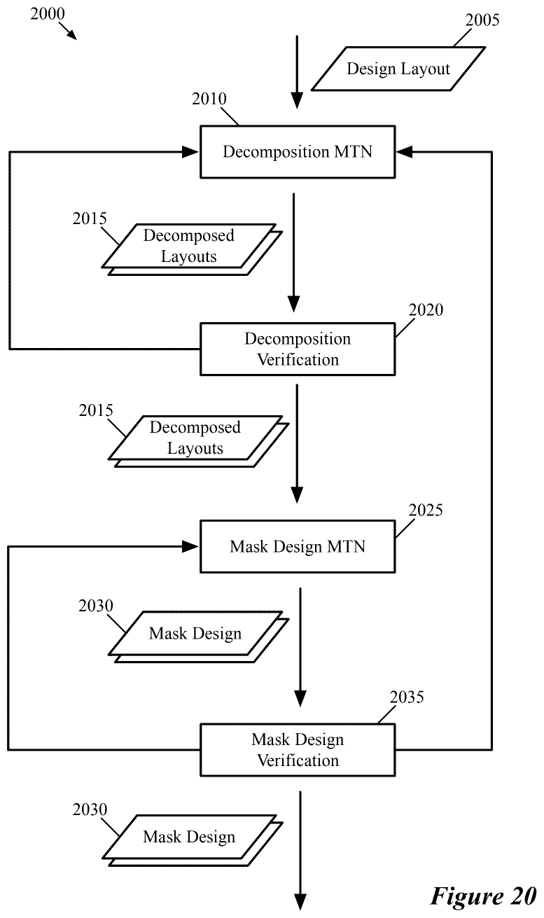

FIG. 20 conceptually illustrates an overall process 2000 for decomposing a layout (i.e., performing multi-patterning or color assignment for the layout) and designing a set of masks for the layout using a set of MTNs. As shown, a design layout 2005 is provided to a decomposition MTN 2010, which generates decomposed layouts 2015. The MTN 2010 receives a layout for a layer (or a portion of such a layer) and outputs a decomposition that assigns the features of the layout to multiple separate layouts (i.e., performs color assignment). In some embodiments, different MTNs may be used to decompose layouts into different numbers of separate layouts (e.g., one network for double patterning, another network for triple patterning, etc.). In other embodiments, the network 2010 is trained to assign the features of the layout into an optimal number of separate layouts.

Some embodiments perform a verification process 2020 on the decomposed layouts 2015. This verification process may use the verification techniques described above that use a shape prediction MTN and/or a violation detection MTN, in some embodiments. Ideally, the decomposition MTN 2010 (or multiple MTN instances in the case of tiling) will have optimally assigned the features of the design layout such that the fitness score for the decomposition is below a threshold and no iterative process is required. However, if the decomposition should be performed again, some embodiments use the decomposition MTN 2010 again. To ensure that the MTN 2010 (typically a deterministic algorithm) does not output the same decomposition (i.e., the same coloring assignments for the design layout features), some embodiments modify the input into the MTN 2010. Specifically, some embodiments pre-assign several features differently than in the previous decomposition. For instance, if two nearby features were assigned to the same layout (i.e., the same color) by the initial decomposition, some embodiments pre-assign these to two separate layouts (i.e., different colors).

If the decomposition is verified, these decomposed layouts 2015 are provided as input to a mask design MTN 2025 in some embodiments. This MTN 2025 receives a layout (e.g., the layout with features assigned to a single color) and outputs a mask design for that layout. Thus, the mask design MTN 2025 receives each of the separate layouts 2015 as a separate input and outputs a mask design for each of these layouts, according to which a set of masks can be fabricated. Other embodiments, rather than using such a network for mask design, use existing OPC or ILT processes to generate the masks for each of the separate layouts 2015.

Some embodiments then perform a mask design verification process 2035 on the mask designs 2030. The mask design verification, in some embodiments, simulates the manufactured IC layer based on the mask designs 2030 (e.g., using lithography simulation or an MTN), then verifies that the simulated manufactured IC layer (i) has minimal manufacturability violations and (ii) adequately matches the target IC layer (based on the design layouts). If the mask design is not verified (i.e., either results in too many manufacturability violations or fails to adequately match the target IC layer, some embodiments either return to the mask design MTN 2025 (modifying the input in such a way as to produce new mask designs) or to the decomposition MTN 2010 (modifying the input by, e.g., pre-assigning a subset of the features of the design layout to different layouts).

In some embodiments, rather than providing the entirety of the design layout as an input to a very large MTN, the layout decomposition tool divides the design layout into tiles and uses each tile as a separate input into the decomposition MTN (e.g., the same instance of the MTN or multiple separate instances). For each tile, the MTN performs a separate assignment of the design layout features within the tile, which are then stitched together for the layout as a whole. In some such embodiments, this allows the parallelization of the assignments, as multiple MTN instances can assign features for multiple tiles in parallel.

Dividing the design layout into tiles provides benefits both for training of the network (described below) as well as for inference (decomposing new design layouts). For one thing, tiling the design layout enables parallel processing of multiple tiles in some embodiments (although other embodiments propagate information from one tile to the next, reducing some of the parallelization).

Furthermore, the smaller inputs bound the size of the network while enabling the network to handle design layouts of any size. A typical convolutional neural network receives images up to a maximum size, with smaller inputs zero-padded around the edges to reach that size. Given this, such a network would typically need to be fairly large in order to handle any size of design layout (which could vary between different IC designs and even between different layers of one IC design). Using tiling bounds the network to a predetermined size, and any design layout can be divided into tiles of that size or smaller (with smaller tiles using zero-padding for input). In addition, the smaller size enables the network to run more quickly and use less memory. While some MTNs are implemented in datacenters with very large amounts of available memory, others may be implemented on a single device (e.g., on a specialized application-specific IC (ASIC)). Even networks implemented in a datacenter (e.g., using numerous graphics processing units (GPUs) and/or tensor processing units (TPUs)) can benefit from the reduction in size.

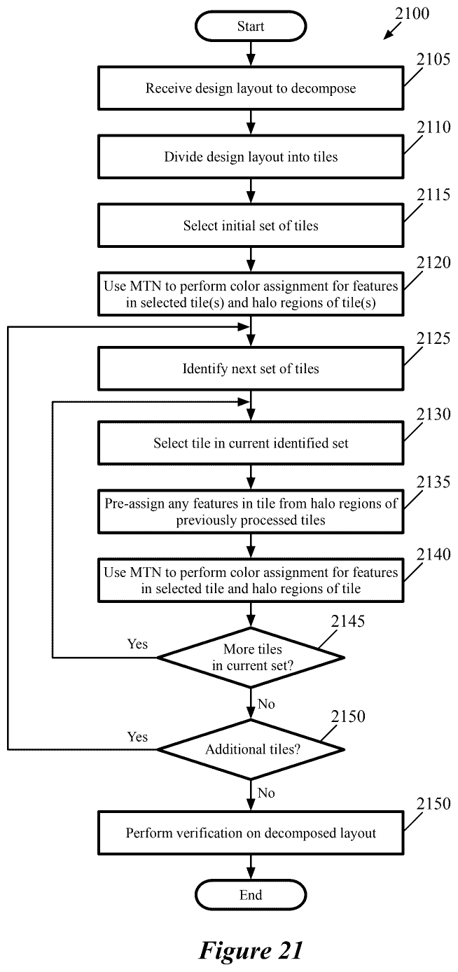

FIG. 21 conceptually illustrates a process 2100 of some embodiments for using an MTN to decompose a layout that is divided into tiles. The process 2100 may be performed by a layout decomposition tool in some embodiments, which makes use of an MTN to perform the actual coloring assignments.

As shown, the process 2100 begins by receiving (at 2105) a design layout (e.g., for a layer of an IC) to decompose. The design layouts of some embodiments include numerous features, or shapes. These features represent layer components, such as interconnect (wiring) segments for a metal (wiring) layer, via holes for a via layer, etc. The design layout may restrict features to specific angles or allow an omnidirectional set of features. Common design layouts with the features restricted to certain angles include Manhattan layouts (i.e., with all of the features arranged either horizontally or vertically) or layouts allowing specific diagonal angles (e.g., features arranged horizontally, vertically, and at 45° angles). Other layouts include omnidirectional rectilinear layouts (i.e., layouts with entirely straight lines but at any angle) as well as curvilinear layouts (i.e., layouts in which some of the features may have curved edges). For ICs, the received design layout is typically the output of a physical design process that includes operations such as floorplanning, placement, routing, and compaction (and has often been verified by a layout verification tool).

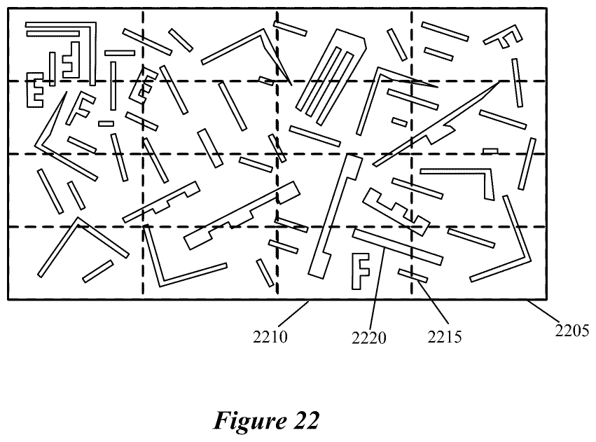

The process 2100 then divides (at 2110) the design layout into tiles. FIG. 22 conceptually illustrates the tiling of a design layout 2200. As shown, the design layout 2200 includes numerous features (e.g., representing interconnect segments of a metal layer) at various omnidirectional angles. It should be understood that a typical design layout for a modern IC layer will have many more features than are shown in the design layout 2200. In this case, the design layout 2200 is divided into 16 tiles, each of which is equally sized and includes a separate subset of the features.

As noted, in some embodiments the MTN performs a separate assignment of the features within each tile. However, in the most simplistic application, this can result in conflicts between tiles. For instance, the features 2215 and 2220 in the design layout 2200 both span between tiles 2205 and 2210. If these two features are assigned to the same color by the MTN for the tile 2205 but different colors for the tile 2210, this can create a conflict (i.e., equivalent to a stitch in traditional coloring algorithms). Some embodiments handle these conflicts by using a boundary conflict checking process after all of the tiles have had their features assigned (e.g., using a separate MTN that performs the boundary checks or another algorithm). If needed, some embodiments perform a second round of color assignment with, e.g., offset tiles and the initial color assignment as a biasing factor, repeating these operations until a valid conflict-free color assignment is found.

As shown in the process 2100, To solve this issue of conflicts between tiles, other embodiments (i) incrementally input the tiles through the MTN (e.g., one tile at a time rather than providing numerous tiles to numerous instances of the MTN in parallel) and (ii) propagate information from one tile to the next. Some embodiments include a halo region around each tile as part of the input to the MTN so that the input area for one tile overlaps with multiple other tiles.

Returning to FIG. 21, the process 2100 selects (at 2115) an initial set of tiles. This may be a single tile or a set of multiple tiles, in different embodiments. In some embodiments, the initially selected tile is the center tile of the tiled layout. Other embodiments select multiple initial tiles (e.g., in a checkerboard-like pattern). The process 2100 then uses (at 2120) an MTN to perform color assignment for the features in the selected tile(s) as well as in halo regions of those tile(s).

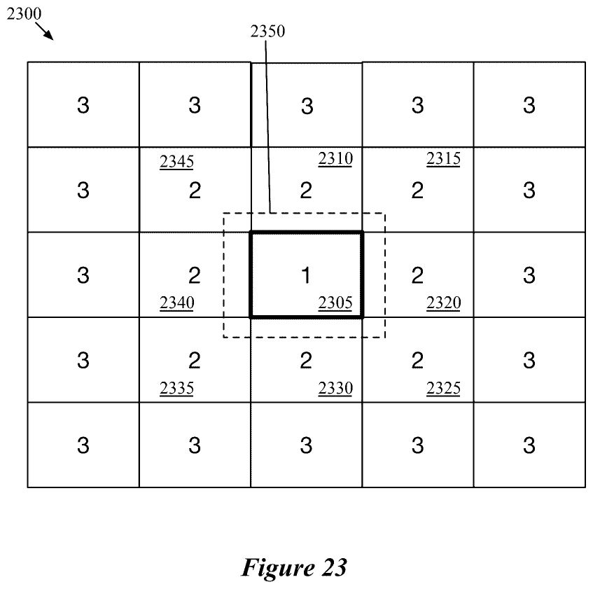

As an example, FIG. 23 conceptually illustrates a design layout region 2300 divided into a set of twenty-five tiles. This may represent an entire design layout or a portion of a design layout. In some embodiments, color assignment is performed first for any features at least partially within the center tile 2305, which is designated with the number 1 (i.e., by providing the center tile to a decomposition MTN). The figure also illustrates a halo region 2350 around the center tile, which includes portions of the eight surrounding tiles 2310-2345. In some embodiments, the input to the MTN (e.g., the set of pixels provided as input) includes the entirety of the center tile 2305 and its halo region 2350. As a result, the output of the MTN not only includes coloring assignments for the features entirely within the center tile 2305 but also any features at least partially within the halo region 2350.

The process 2100 then identifies (at 2125) a next set of tiles and selects (at 2130) a tile in this current identified set. In some embodiments, after the color assignment of an initial tile's features, the decomposition process moves on to the eight surrounding tiles, then the 16 tiles surrounding these eight tiles, and so on. As shown in FIG. 23, after the first tile 2305, the decomposition process provides each of the eight tiles 2310-2345 (designated with the number 2), with their corresponding halo regions, to the MTN. Because the color assignment of one of these tiles will affect the color assignment of other tiles, some embodiments continue to only propagate one tile at a time through the MTN. For example, the color assignment for tile 2310 and its halo region will include features within tile 2315.

The process 2100 then pre-assigns (at 2135) any features in the selected tile that are part of the halo regions of previously processed tiles and, therefore, have previously been assigned. With this pre-assignment, the process 2100 uses (at 2140) the MTN to perform color assignment for features in the selected tile and the halo regions of that tile (if those halo regions have not already had their features pre-assigned).

When providing tiles to the MTN for which a subset of the features have been assigned because the features are at least partially within the halo region of another tile or within the other tile itself (and in the halo region of the current tile), this pre-assignment is indicated in the input data for the MTN in some embodiments. In different embodiments, the MTN treats this as a strict assignment of the features to particular layouts (i.e., particular colors) or as a preference that can be modified in certain cases. Thus, by reference to FIG. 23, if starting this second “ring” of tiles with the upper-middle tile 2310 and proceeding clockwise, a subset of the features within tile 2310 would have been assigned during the processing of the center tile 2305, a subset of the features within tile 2315 would have been assigned during the processing of the center tile 2305 and the tile 2310, and so on.

The process 2100 then determines (at 2145) whether more tiles remain in the current set. If additional tiles remain, the process 2100 returns to 2130 to select the next tile and assign the features of that tile. As noted, some embodiments proceed around each ring of tiles one tile at a time. Once all of the tiles in the current set are processed, the process 2100 determines (at 2150) whether additional tiles remain in the design layout. If additional tiles remain, the process returns to 2125 to identify the next set of tiles.

Again by reference to FIG. 23, after processing each of the tiles 2310-2345 in the second ring, the subsequent ring of tiles (designated by the number 3) would be processed. In some embodiments, each ring of tiles is processed in an order such that the last tile processed for that ring is in one of its corners (e.g., the tile 2345 in the top-left corner in this example).

After all of the tiles have been processed (and thus all of the features assigned to the layouts of the decomposition), the process 2100 of some embodiments performs (at 2155) verification on the decomposed layout, then ends. Some embodiments perform this verification on the coloring assignment by using a shape prediction MTN followed by a violation detection MTN) as described above. In some embodiments, if the decomposition is not good enough, different inputs are provided to the decomposition MTN (which is typically deterministic if provided the same input). Different embodiments may use a different starting tile, the same starting tile but a different ordering for the subsequent tiles, offset tile boundaries, and/or differently sized tiles. This process can be repeated until an adequate decomposition is found. In addition, after a number of iterations, some embodiments may use a different MTN that uses a larger number of separate layouts (e.g., triple-patterning rather than double-patterning).

Rather than radiating outwards from a center tile, other embodiments use different patterns to process tiles of a design layout. For instance, some embodiments begin in one corner of the design layout and then proceed in columns or rows of tiles (still using the halos to pre-assign features in neighboring tiles).

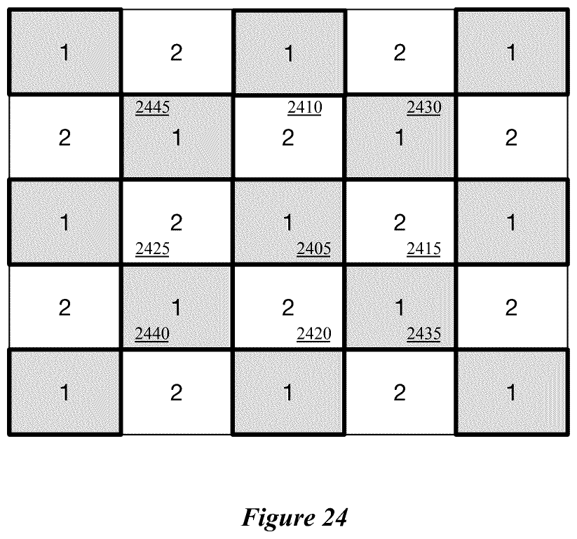

Still other embodiments use a checkerboard pattern to allow for parallelization of some of the tiles, as conceptually illustrated in FIG. 24. In this case, different embodiments cither do not use halo regions or only use halo regions directly above, below, to the left, and to the right of each tile in a first pass. In FIG. 24, each of the tiles indicated with a 1 and filled in gray have their features assigned during a first pass. In some such embodiments, all of these tiles can be processed in parallel, depending on the memory and compute limitations of the system executing the MTN (e.g., by the use of multiple GPUs and/or multiple threads of one or more GPUs). When processing the tile 2405, some embodiments use no halo regions while other embodiments use halo regions that occupy portions of the four tiles 2410-2425 but do not include any of the portions of the tiles 2330-2345. If no halo regions are used, then only features that overlap with previously processed tiles are pre-assigned for the second and subsequent sets of tiles. If halo regions are used, then in the subsequent pass for the remaining tiles, large sections of these tiles would already be assigned via the halo regions of the first-pass tiles.

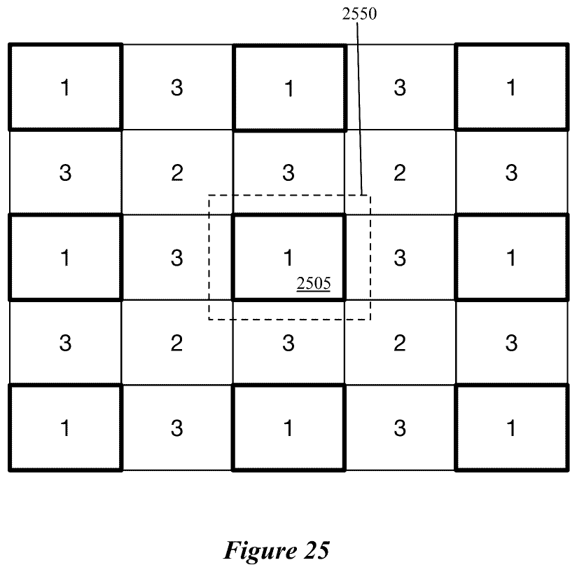

Another pattern used by some embodiments is shown in FIG. 25. In this case, the first pass of tiles includes only tiles with no common boundaries, including diagonal boundaries. Using this configuration enables the use of full halo regions (i.e., in the same manner as the example of FIG. 23) for each first-pass tile. For instance, the halo region 2550 of tile 2505 includes portions of all eight surrounding tiles. After the first-pass tiles (shown by the number 1) are processed (potentially in parallel), the second-pass tiles (shown by the number 2) located on the diagonals of these tiles can then also be processed in parallel, with large portions of their features pre-assigned based on the halo region assignments of the first-pass tiles. The remaining tiles (shown by the number 3) can be processed next.

As noted above, the tiling of the design layout also simplifies training of the MTN. For some types of deep learning models, the smaller input size requires fewer total parameters that need to be modified. In addition, each training batch can be propagated more quickly and uses less data as there is less memory required. Furthermore, the tiling allows the creation of a much larger group of training inputs. For instance, to generate one thousand training inputs without tiling would require optimizing the decompositions of one thousand different design layout. On the other hand, if each design layout can be divided into five hundred tiles, then only two decompositions need to be optimized in order to generate one thousand training inputs.

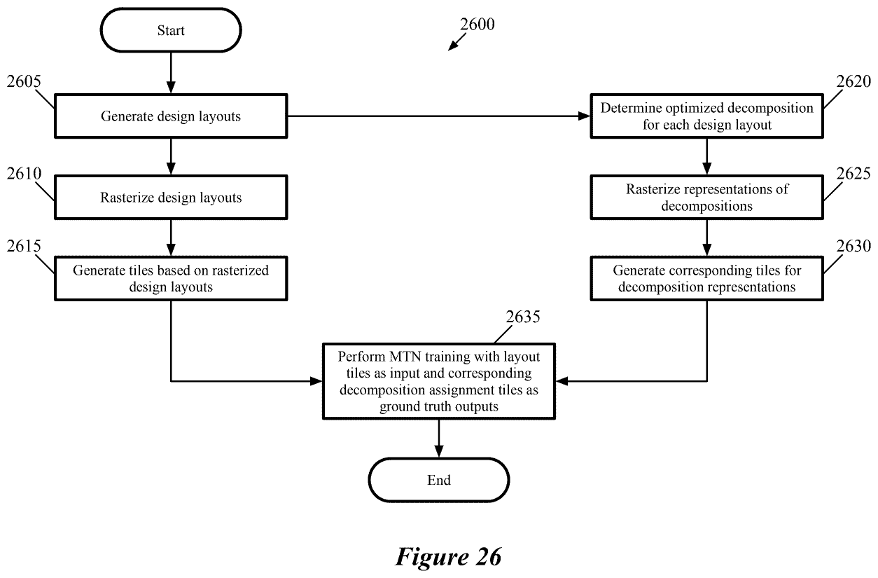

FIG. 26 conceptually illustrates a process 2600 of some embodiments for creating training data and using this training data to train a decomposition MTN. This process 2600 generates known inputs (design layouts) as well as corresponding ground truth outputs (optimized decompositions) for these inputs. In some embodiments, the process 2600 is performed outside of the layout decomposition tool (e.g., by a separate training process) so that the trained MTN can be used by such a tool.

As shown, the process 2600 generates or receives (at 2605) a set of design layouts. In some embodiments, the design layouts represent the type of layouts that will be decomposed by the network once the network is trained. That is, if the MTN is to be used exclusively for metal (wiring) layers, then the design layouts used for training should be design layouts for metal layers. If the MTN is to be used for via layers, then the design layouts used for training should be via layers. Similarly, in the context of wiring layers, if the MTN is only going to be used for decomposing Manhattan wiring layers, then only Manhattan design layouts need to be used for training. On the other hand, if the design layouts to be decomposed at inference include omnidirectional rectilinear layouts and/or curvilinear layouts, then design layouts with these features should be included in the training data.

The process 2600 then splits into two sub-processes. The first sub-process includes operations 2610 and 2615 that generate the known inputs for the MTN training, while the second sub-process includes operations 2620-2630 to generate the corresponding ground truth outputs. Specifically, the process 2600 rasterizes (at 2610) the design layouts. That is, for each design layout to be used for training, a rasterized layout is generated. The rasterization process that converts geometric data into pixel data for a set of shapes (e.g., of a design layout) is described above.

In addition, the process 2600 generates (at 2615) tiles based on the rasterized design layouts. Some embodiments tile the design layouts based on a maximum size input for the network to be trained. That is, an MTN (e.g., a convolutional neural network) typically receives a fixed-size input, and the tiles are generated from the design layouts based on this size. Some embodiments, however, may generate multiple sets of tiles covering a single design layout. For instance, if a design layout is 3000×3000 pixels and the input size is 100×100 pixel tiles, then an initial pass can generate 900 tiles (a 30×30 grid of tiles) that fully cover the design layout. However, some embodiments also generate additional tiles. By offsetting the starting point by 50 pixels in each direction, another 841 different tiles could be generated (a 29×29 grid of tiles). The outer edge could also be used to generate 50×100, 100×50, and 50×50 tiles that are filled in with zero-padding, to be used to train the MTN to handle zero-padding. Similarly, interior tiles of different sizes could be selected in order to generate tiles with different amounts of zero-padding around the edges.

The process 2600 also determines (at 2620) an optimized decomposition for each design layout. In some embodiments, these decompositions are determined via the iterative processes described above (i.e., by iteratively assigning features of the design layouts to separate layouts, generating predicted manufactured layers based on the assignment, and scoring the assignment based on the predicted manufactured layers). In other embodiments, the decompositions are determined via traditional (e.g., graph coloring) methods.

The process 2600 then rasterizes (at 2625) the representations of the decompositions. In some embodiments, rasterizing a decomposition requires more than just simple pixel values because features assigned to different colors need to be differentiated. For instance, some embodiments use a separate value for each “color” (e.g., similar to RGB values). In this case, pixels within a feature assigned to a first color have a 1.0 value for that first color but a 0.0 value for any other colors, while pixels within a feature assigned to a second color have a 1.0 value for the second color and a 0.0 value for any other colors. Edge pixels of a feature have values between 0.0 and 1.0 for the color to which the feature is assigned and 0.0 values for any other colors, while pixels not belonging to any of the features are assigned 0.0 values.

The process 2600 also generates (at 2630) tiles for the decomposition representations that correspond to the input tiles generated for the design layouts. That is, each tile generated for the design layout should have a corresponding ground truth output tile generated from the corresponding area of the rasterized decomposition. The rasterized decompositions should have the same pixel dimensions as their corresponding rasterized design layouts, so the same set of operations can be performed to generate the decomposition tiles.

Finally, the process 2600 performs (at 2635) MTN training with rasterized design layout tiles as input and the rasterized decomposition tiles as the corresponding ground truth outputs. To train the network, some embodiments propagate batches of known inputs (the rasterized layout tiles) through the MTN to generate outputs (color assignments) for each input. The training process then compares these generated outputs to the ground truth outputs (i.e., compares the predicted manufactured layers to the simulated manufactured layers) to compute error values for each input. These error values are used to compute the value of a loss function (e.g., a cross-entropy loss function), in some cases in conjunction with other loss function terms (e.g., regularization terms, etc.). This loss function is backpropagated through the MTN to compute gradients for configurable parameters (e.g., weight values, bias values, etc.) and adjust these configurable parameters. Some embodiments perform this process iteratively (e.g., using a batch of inputs for each iteration) until the MTN is adequately trained.

If tiling is not used for the decomposition MTN, then the process 2600 can be modified to train such a network by using a larger number of design layouts and skipping the tiling operations. Conversely, the shape prediction and violation identification networks described above can operate on tiles rather than entire design layouts or predicted manufactured layers in some embodiments. That is, some embodiments train the shape prediction MTN by tiling the input design layouts and simulated manufactured layers, then similarly tile the decomposed layouts during inference. Along these lines, some embodiments train the violation identification MTN by tiling the input predicted manufactured layers and the output violation sets, then similarly tile the predicted manufactured layers during inference.

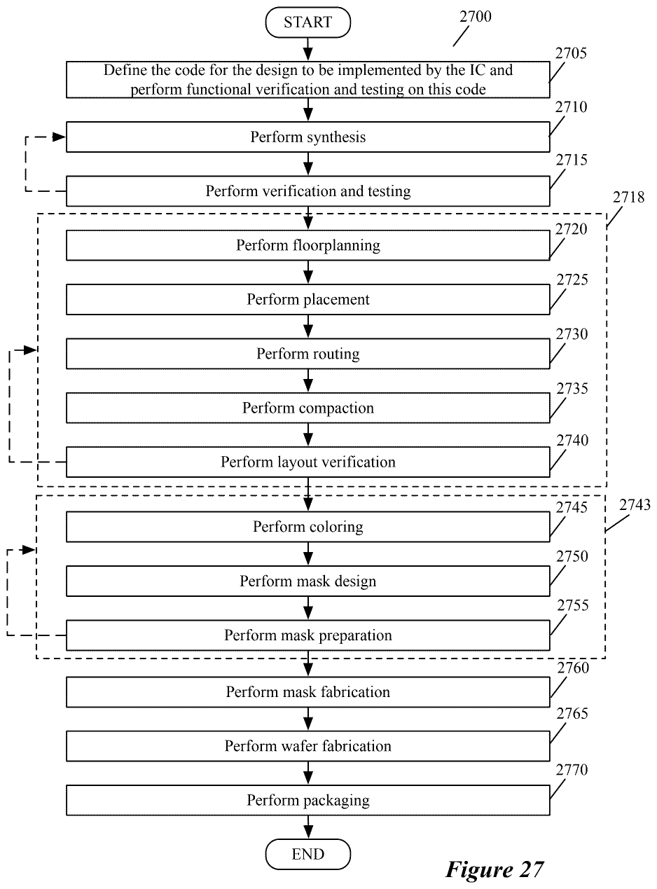

The above-described embodiments describe using various deep learning methods to decompose a design layout prior to mask design. This multi-patterning operation is one step in the overall process to design and manufacture an IC. FIG. 27 conceptually illustrates an example of one such process for designing and manufacturing an IC. The process 2700 of this figure uses the design layout decomposition techniques described above to ensure that the features of the design layout are properly assigned to different layouts for which masks are designed.

The process 2700 begins (at 2705) by defining the code that specifies the IC design and performing functional verification and testing on this code. In some embodiments, the process uses one of the common hardware description languages (HDL) to specify the code. The HDL code in some embodiments describes the desired structure, behavior, and timing of the IC. To perform functional verification and testing on the code for the IC, some embodiments specify one or more modules and/or circuit components in the code and check the specified modules and/or circuit components for functional accuracy.

Next, the process 2700 performs (at 2710) a synthesis operation, which converts the HDL description into a circuit representation that commonly includes digital circuit components, such as logic gates, flip-flops, and other larger digital components (e.g., adders, multipliers, etc.). The synthesis operation is typically performed by a synthesis tool.

At 2715, the process 2700 performs verification and testing on the circuit representation that is produced by the synthesis operation. In some embodiments, the verification and testing checks the circuit representation to determine whether this representation meets desired timing constraints and satisfies any other constraint of the HDL code. When the verification and testing fails (e.g., if a portion of the circuit representation fails to meet a constraint), the process 2700 returns to step 2710 (as denoted by a dashed arrow line) to reperform synthesis to modify the circuit representation to resolve this failure.

When the verification and testing at 2715 passes, the process 2700 performs a set of physical design operations 2718, which include operations 2720-2735 between which the process 2700 can iterate through multiple times as further described below. At 2720, the process 2700 performs a floorplanning operation that defines a general location for some or all of the circuit blocks (e.g., for various large circuit blocks). For instance, in some embodiments, floorplanning divides the design layout into one or more sections devoted to different purposes (e.g., ALU, memory, decoding, etc.), and assigns some or all of the circuit blocks to these sections based on the purposes served by these blocks.

At 2725, the process 2700 performs a placement operation, which is based on the floorplanning data and defines a specific location and orientation in the design layout for each circuit block. The placement operation in some embodiments is an automated process that tries to find an optimal placement for each circuit block based on one or more optimization criteria, such as congestion or estimated length of interconnects (e.g., metal wires) needed for connecting the nets associated with the circuit blocks. A net in some embodiments includes a set of two or more pins of one or more circuit blocks that need to be connected electrically (e.g., through a set of wires, contacts, and/or vias). After performing the placement operation, the process 2700 might return to the floorplanning operation if it determines that the floorplanning should be revised to improve the result of the placement operation.

Once the placement operation is completed satisfactorily, the process performs (at 2730) a routing operation to define the route needed to connect each net (i.e., to connect each set of pins that needs to be interconnected). Each defined route includes one or more interconnect segments (also called wire segments) that traverse one or more interconnect layers (also called wiring layers), and one or more vias and/or contacts that connect pins and/or wire segments on different wiring layers.

To define the routes, some embodiments divide the routing operation into a global routing operation and a detailed routing operation. For each net, global routing defines a global route that more generally defines the route for the net (e.g., defines a general area in the design layout traversed by the route). For instance, in some embodiments, the global router divides an IC into individual global routing areas, called Gcells. Then, a global route (Groute) is created for each net by listing the global routing areas (the Gcells) that the Groute for the net should pass through.

The detailed routing defines the actual route for each net (e.g., the route that connects the set of pins that forms the net). As mentioned above, each defined route includes one or more interconnect segments that traverse one or more interconnect layers, and one or more vias and/or contacts that connect pins and/or wire segments on different interconnect layers. In performing its detailed routing operation, the detailed router of some embodiments uses the global router's Groute data, e.g., by biasing its detail route search for the net to the Groute regions traversed by the Groute defined by the global router.

During or after the detailed routing operation, the process 2700 performs a design rule check (DRC) operation to ensure that the defined routes do not violate design rules. One example of the design rule check that is done for a route is to ensure that the route is not closer than an acceptable minimum spacing requirement on each layer traversed by the route to another route or another component in the design layout on that layer. Routes that violate minimum spacing constraints can cause undue capacitance and, in some cases, electrical shorts on the IC.

The process 2700 in some embodiments can iterate through the global and detailed routing multiple times to identify better Groutes for some nets in order to improve the detailed routes for these nets or other nets. Also, the process 2700 in some embodiments can return from either of these routing operations to an earlier operation in the EDA flow (e.g., to the placement operation) in order to improve the results of this earlier operation to improve the routes defined by the later routing operation.

After routing, the process 2700 performs (at 2735) compaction operations. In some embodiments, the compaction operation compresses the design layout in one or more directions to decrease the size of the IC die (e.g., to decrease the two-dimensional area of the IC die) that would be manufactured based on the design layout. Reducing the size of the IC improves the performance of the IC in some embodiments. A compacted design layout also lowers costs of the ICs manufactured using the design layout by allowing more ICs to be produced for a given wafer size.

After the compaction operation, the process 2700 performs a layout verification operation (at 2740) to ensure that the compacted design layout (e.g., the compacted routes in this design) to ensure that the layout meets one or more verification criteria. This verification operation includes a DRC operation that ensures that the compacted design layout does not violate design rules. One example of the DRC that is done for a route is to ensure that the route is not closer than an acceptable minimum spacing requirement on each layer traversed by the route to another route or another component in the design layout on that layer. Other examples of the DRC include performing minimum area, minimum width, and maximum curvature of shapes (e.g., routes, pins, contacts, vias, or other components) of items in the design layout, as described above.

The layout verification in some embodiments includes other operations, such as extraction. Extraction in some embodiments computes parasitic values (e.g., parasitic capacitance values or parasitic inductance values) exerted on items (e.g., wire segments) in the design layout. In some embodiments, the extraction operation computes capacitance coefficients for one or more conductive components in the design layout (e.g., for each wire segment of a route, or for the entirety of each route, in the design layout), and uses the capacitance coefficients to compute parasitic influence (e.g., capacitance, resistance, or inductance) on the conductive component(s).

After the compaction operation at 2735 or the subsequent verification operation 2740, the process 2700 in some embodiments can return to an earlier operation in the EDA flow (e.g., to the placement operation, to the global routing operation, or to the detailed routing operation) in order to improve the results of this earlier operation to improve the compacted design defined by the later compaction operation. For instance, when the design is not verified at 2740 (e.g., if a problem with the design is detected during verification), the process 2700 returns to an earlier physical design operation 2720 to 2735 to reperform this physical design operation, and any subsequent physical design operation, for a portion or for the entire design layout. In some embodiments, the design layout that exists after the compaction operation and that passes the subsequent verification operation 2740 on this layout is the end result of the physical design process, is called the physical design layout, and is used as the input to the subsequent operations 2745-2755 that form the manufacturing sub-process of the process 2700.

In some embodiments, the physical design sub-process includes other operations that are not displayed in FIG. 27. These other operations are not displayed for purposes of brevity. Examples of such operations include partitioning, power planning, and clock tree synthesis (CTS). In some embodiments, partitioning divides the design layout into similar-sized subsets and ensures a minimum number of connections between subsections. Power planning defines the power delivery network (PDN) that includes the interconnects for delivery power from the power supply circuit to circuits defined by the IC design layout. CTS in some embodiments defines a clock delivery network for delivering one or more clock signals to circuits defined by the IC design layout. CTS in some embodiments also inserts buffers and/or inverters along the clock signal paths on the clock delivery network in order to balance the load and decrease or eliminate any clock skew or delay.

Once physical design operations 2718 are completed and the design layout is finalized, the process 2700 performs a set of mask production operations 2743, which include operations 2745-2760. These processes collectively produce a set of one or more masks for each layer of the IC based on the design layout which, when used to fabricate the IC, should result in an IC (or multiple ICs) that match the design layout as closely as possible.

At 2745, the process 2700 performs a coloring operation for each layer of the design layout. The coloring operation decomposes the design layout for a layer into multiple (e.g., two, three, etc.) separate layouts for the purpose of mask production by assigning each feature in the layout to one of multiple “colors”. For certain IC design layers, the features (e.g., the routes, pins, contacts, vias, etc.) are packed too closely for the features to be printed on a wafer using a single mask. As described above, in some embodiments, the coloring operation identifies an optimal decomposition for a layer by iteratively assigning the features in the layer to different colors (e.g., using a graph coloring algorithm) and scoring the decomposition. Some embodiments use the MTN-based techniques described above to perform the decomposition, simulate the wafer results based on a given decomposition, and/or compute the scores for each decomposition. In some embodiments, this coloring operation is optional and can be skipped for some or all of the IC layers.

After the coloring operation, the process 2700 performs mask design (at 2750) or mask layout generation. Mask design generates, for each layer of the IC, the layout for one or more masks (i.e., one mask for each color) that will optimally create the shapes defined in the layout during fabrication of the IC. Some embodiments use commonly known techniques, such as OPC (optical proximity correction) and/or ILT (inverse lithography technology) operations. An ILT system, for instance, iteratively defines a potential mask layout, performs lithography simulation to simulate the wafer shapes that would be manufactured using the potential mask layout, compares this simulation to a set of target wafer shapes, and updates the mask layout based on the comparison (the inverse lithography step). After numerous such iterations, the ILT system determines an optimized mask design for a given layout.

During or after the mask design operation, the process 2700 performs a mask rule check (MRC) operation (not shown separately in the figure) to ensure that the shapes defined in the mask layout do not violate MRC rules. Examples of the MRC rules include minimum spacing, minimum width, maximum curvature, and minimum area for shapes in the mask layout.

The process 2700 then performs a mask preparation operation at 2755. In some embodiments, the mask preparation operation 2755 includes operations that prepare a mask writer (e.g., an electron beam mask writer) to fabricate a particular mask based on the mask design, such as mask data preparation (MDP) and Mask Process Correction (MPC). MDP in some embodiments prepares the mask layout for a mask writer. This operation in some embodiments includes “fracturing” the data into trapezoids, rectangles, or triangles.

The MPC operation, in some embodiments, accounts for various physical effects during mask production to “correct” the mask layout such that the fabricated mask will more closely match the mask layout. Because of these physical effects, a mask writer following the specific shapes of the mask design will produce a mask that does not perfectly match that mask design. MPC in some embodiments either geometrically modifies these shapes and/or modifies pixel doses for a mask writer such that the resulting mask shapes will more accurately match the desired shapes of the mask design. MDP may use as input the generated mask layout or the results of MPC. MPC may be performed as part of a fracturing or other MDP operation. Other corrections may also be performed as part of fracturing or other MDP operations. Also, in some embodiments, the mask preparation operation calculates several possible mask images by using charged particle beam simulation. Additional description of the mask design and mask preparation operations is provided in U.S. Pat. No. 8,719,739, entitled “Method and System for Forming Patterns Using Charged Particle Beam Lithography”, which is incorporated herein by reference.

Other embodiments, that do not use MPC to modify the mask shapes or pixel doses for a mask writer in order to produce the desired mask shapes, perform a separate mask simulation operation followed by a wafer simulation operation as a verification of the output of the mask design operation 2750. Mask simulation in this case simulates the production of each mask using the respective generated mask layout, while wafer simulation simulates the resulting wafer shapes based on these simulated masks to verify that the resulting wafer shapes will be close enough to the desired wafer shapes.

In some embodiments, after performing mask preparation and/or simulation (or after performing a mask rule check prior to the mask preparation), the process 2700 can return to an earlier operation in the mask production operations 2743 (e.g., to coloring 2745 or mask design 2750) in order to improve the results of this earlier operation and thereby improve the eventual fabricated mask. Due to the high expenses of fabricating a mask, it is generally desirable to have the mask designs optimized before fabrication. In some embodiments, the process 2700 can iteratively repeat the mask production operations 2743 in order to improve the quality of the overall generated mask or can return to one of the earlier physical design operations 2718, as described above.

Once the mask layout is generated and verified, the process 2700 fabricates (at 2760) the one or more masks specified for all the layers of the IC based on the mask layout. Mask generation transforms each mask image (also referred to as a mask layer, in some embodiments) of the mask layout into one or more lithographic masks in some embodiments. In some embodiments, the MPC operation described above is actually performed within the mask writer as the mask writer fabricates a given mask based on the mask design for that mask (i.e., to modify the mask writer output in order to better produce the desired mask).

Once the masks are generated, the process 2700 performs (at 2765) wafer fabrication, which uses the generated masks to manufacture multiple IC dies on an IC wafer (e.g., a silicon wafer). The masks for the substrate and each wiring layer are used to generate the devices and wiring on the substrate and each wiring layer of each IC die. Each IC die is usually tested. During the testing of the IC dies, if it is determined that the IC has a defect because of its design or its masks, the process 2700 has to return to an earlier operation to improve its design layout, its mask layout, or its mask production operation. Lastly, the process 2700 performs (at 2755) packaging, which places each IC die in one chip package. Packaging in some embodiments includes slicing a wafer into multiple IC dies and placing each die on a substrate, which is then encapsulated to form a chip package. After performing packaging, the process 2700 ends.

Although several embodiments were described above by reference to performing design layout decomposition to perform multi-patterning operations on IC designs used to design and/or manufacture an IC, one of ordinary skill will realize that other embodiments are used to perform similar multi-patterning operations for design layouts that are created for designing and manufacturing silicon interposers (e.g., wiring patterns on silicon interposers).

Still other embodiments are used to design and manufacture other patterns on other types of substrates. For instance, some embodiments use the above-described design layout decomposition processes to perform multi-patterning of design layouts for designing displays such as flat-panel displays (e.g., monitors, televisions, glasses, etc.) or curved displays (e.g., displays for virtual reality or augmented reality headsets). Such design layouts define patterns of controllable pixels on a display substrate. Still other embodiments use the above-described tile-based parasitic extraction processes to check the design layouts for designing other patterns of other elements for other substrates. Examples of such other substrates include substrates used to manufacture micro-electromechanical (MEMS) and other such similar devices.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

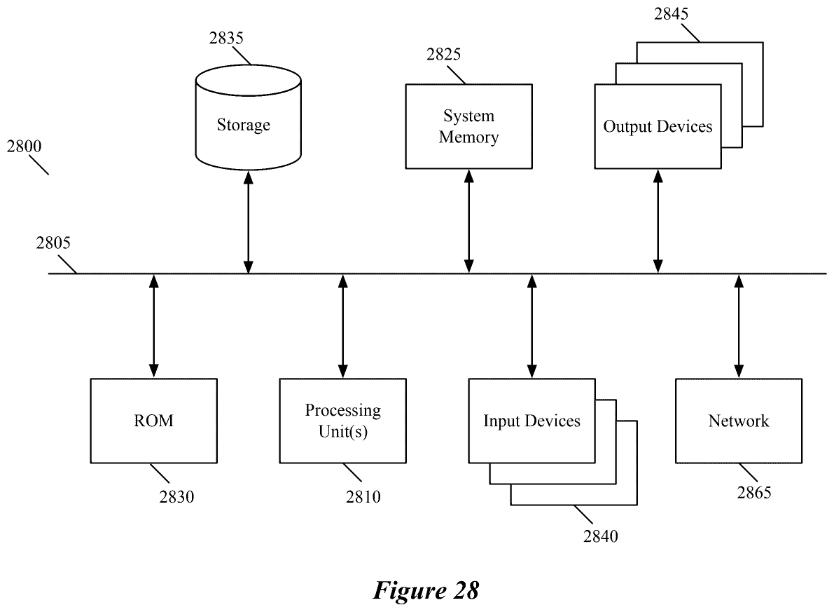

FIG. 28 conceptually illustrates a computer system 2800 with which some embodiments of the invention are implemented. The computer system 2800 can be used to implement any of the above-described computers and servers. As such, it can be used to execute any of the above-described processes. This computer system includes various types of non-transitory machine-readable media and interfaces for various other types of machine-readable media. Computer system 2800 includes a bus 2805, processing unit(s) 2810, a system memory 2825, a read-only memory 2830, a permanent storage device 2835, input devices 2840, and output devices 2845.

The bus 2805 collectively represents all system, peripheral, and chipset buses that communicatively connect the numerous internal devices of the computer system 2800. For instance, the bus 2805 communicatively connects the processing unit(s) 2810 with the read-only memory 2830, the system memory 2825, and the permanent storage device 2835.

From these various memory units, the processing unit(s) 2810 (e.g., CPUs, GPUs, and/or TPUs) retrieve instructions to execute and data to process in order to execute the processes of the invention. The processing unit(s) may be a single processor or a multi-core processor in different embodiments. The read-only-memory (ROM) 2830 stores static data and instructions that are needed by the processing unit(s) 2810 and other modules of the computer system. The permanent storage device 2835, on the other hand, is a read-and-write memory device. This device is a non-volatile memory unit that stores instructions and data even when the computer system 2800 is off. Some embodiments of the invention use a mass-storage device (such as a magnetic or optical disk and its corresponding disk drive) as the permanent storage device 2835.

Other embodiments use a removable storage device (such as a flash drive, etc.) as the permanent storage device. Like the permanent storage device 2835, the system memory 2825 is a read-and-write memory device. However, unlike storage device 2835, the system memory is a volatile read-and-write memory, such a random-access memory. The system memory stores some of the instructions and data that the processor needs at runtime. In some embodiments, the invention's processes are stored in the system memory 2825, the permanent storage device 2835, and/or the read-only memory 2830. From these various memory units, the processing unit(s) 2810 retrieve instructions to execute and data to process in order to execute the processes of some embodiments.

The bus 2805 also connects to the input and output devices 2840 and 2845. The input devices enable the user to communicate information and select commands to the computer system. The input devices 2840 include alphanumeric keyboards and pointing devices (also called “cursor control devices”). The output devices 2845 display images generated by the computer system. The output devices include printers and display devices, such as cathode ray tubes (CRT) or liquid crystal displays (LCD). Some embodiments include devices such as a touchscreen that function as both input and output devices.

Finally, as shown in FIG. 28, bus 2805 also couples computer system 2800 to a network 2865 through a network adapter (not shown). In this manner, the computer can be a part of a network of computers (such as a local area network (“LAN”), a wide area network (“WAN”), or an Intranet, or a network of networks, such as the Internet. Any or all components of computer system 2800 may be used in conjunction with the invention.

Some embodiments include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, read-only and recordable Blu-Ray® discs, ultra-density optical discs, and any other optical or magnetic media. The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some embodiments are performed by one or more integrated circuits, such as application specific integrated circuits (ASICs) or field programmable gate arrays (FPGAs). In some embodiments, such integrated circuits execute instructions that are stored on the circuit itself.

As used in this specification, the terms “computer”, “server”, “processor”, and “memory” all refer to electronic or other technological devices. These terms exclude people or groups of people. For the purposes of the specification, the terms display or displaying means displaying on an electronic device. As used in this specification, the terms “computer readable medium,” “computer readable media,” and “machine readable medium” are entirely restricted to tangible, physical objects that store information in a form that is readable by a computer. These terms exclude any wireless signals, wired download signals, and any other ephemeral or transitory signals.

While the invention has been described with reference to numerous specific details, one of ordinary skill in the art will recognize that the invention can be embodied in other specific forms without departing from the spirit of the invention. Thus, one of ordinary skill in the art would understand that the invention is not to be limited by the foregoing illustrative details, but rather is to be defined by the appended claims.

We claim:

1. A method for decomposing a layout for a layer of an integrated circuit (IC) into two or more pattern layouts, the method comprising:
receiving a first decomposition of the layout of the IC layer, said first decomposition decomposing the layout into a first set of two or more pattern layouts;
providing the first set of pattern layouts to a set of one or more machine-trained networks (MTNs) to identify a set of violations in the first set of pattern layouts, said set of violations identified based on predicted manufactured shapes that are expected to be produced on the IC layer when the first set of pattern layouts is used to manufacture the IC; and
based on the set of violations, decomposing the layout into a second decomposition, having a second set of pattern layouts, to use to manufacture the IC.

2. The method of claim 1 further comprising, iteratively:
providing a current set of pattern layouts to the set of MTNs to identify a set of violations in the current set of pattern layouts based on predicted manufactured shapes that are expected to be produced on the IC layer when the current set of pattern layouts is used to manufacture the IC; and
based on the set of violations in the current set of pattern layouts, decomposing the layout into an updated decomposition.

3. The method of claim 1, wherein the set of MTNs comprises (i) a first MTN to generate predicted manufactured shapes for each of the first set of pattern layouts and (ii) a second MTN to identify the set of violations based on the predicted manufactured shapes generated by the first MTN.

4. The method of claim 3, wherein each of the pattern layouts is provided as a separate input to the first MTN to generate a separate output of predicted manufactured shapes.

5. The method of claim 4, wherein each of the separate outputs of the first MTN are combined into a single set of predicted manufactured shapes that is provided to the second MTN.

6. The method of claim 3, wherein the first MTN is trained by (i) generating decompositions of layouts, (ii) simulating mask design for the generated decomposed layouts, and (iii) simulating manufacturing of IC layers based on the simulated mask designs.

7. The method of claim 6, wherein the generated decompositions are used as training inputs for the first MTN and the simulated manufactured IC layers are used as ground truth outputs for the training the first MTN.

8. The method of claim 6, wherein the simulated manufacturing of IC layers based on the simulated mask layout designs uses a previously-trained third MTN.

9. The method of claim 3, wherein using the set of one or more MTNs comprises rasterizing each of the separate layouts prior to providing the separate layouts as input to the first MTN.

10. The method of claim 1, wherein the set of MTNs comprises an MTN to generate the predicted manufactured shapes, wherein the method further comprises performing a rule check on the predicted manufactured shapes to identify the set of violations.

11. The method of claim 1, wherein the set of MTNs comprises a single MTN that receives the set of pattern layouts as an input and generates the set of violations as an output.

12. The method of claim 1, wherein the IC layer design layout is rasterized prior to being decomposed into the first set of two or more separate layouts.

13. The method of claim 1, wherein the first decomposition of the IC layer has a first number of pattern layouts and the second decomposition of the IC layer has a second, larger number of pattern layouts.

14. The method of claim 13, wherein the method attempts to use a smallest number of layouts possible because a separate mask is produced for each separate layout.

15. The method of claim 1, wherein the first decomposition is generated by assigning each shape of a plurality of shapes of the layout of the IC layer to one of the pattern layouts.

16. The method of claim 1, wherein the aggregation of each set of two pattern layouts produces the layout for the IC layer.

17. The method of claim 1, wherein decomposing the layout into the second decomposition comprises modifying the first decomposition based on the identified set of violations.

18. The method of claim 1, wherein the second set of pattern layouts are used to generate a set of mask designs, the method further comprising manufacturing a set of masks based on the mask designs and using the manufactured set of masks to manufacture the IC.

19. A non-transitory machine-readable medium storing a program which when executed by at least one processing unit decomposes a layout for a layer of an integrated circuit (IC) into two or more pattern layouts, the program comprising sets of instructions for:
receiving a first decomposition of the layout of the IC layer, said first decomposition decomposing the layout into a first set of two or more pattern layouts;
providing the first set of pattern layouts to a set of one or more machine-trained networks (MTNs) to identify a set of violations in the first set of pattern layouts, said set of violations identified based on predicted manufactured shapes that are expected to be produced on the IC layer when the first set of pattern layouts is used to manufacture the IC; and
based on the set of violations, decomposing the layout into a second decomposition, having a second set of pattern layouts, to use to manufacture the IC.

20. The non-transitory machine-readable medium of claim 19, wherein the set of MTNs comprises (i) a first MTN to generate predicted manufactured shapes for each of the first set of pattern layouts and (ii) a second MTN to identify the set of violations based on the predicted manufactured shapes generated by the first MTN.
